(19) United States
(12) Patent Application Publication
(10) Pub. No.: US 2015/0255258 A1
(43) Pub. Date: Sep. 10, 2015

(54) PLASMA PROCESSING APPARATUS AND SUBSTRATE PROCESSING APPARATUS PROVIDED WITH SAME

(71) Applicant: TOKYO ELECTRON LIMITED, Tokyo (JP)

(72) Inventors: Toshihisa Nozawa, Miyagi (JP); Masahide Iwasaki, Miyagi (JP); Takenao Nemoto, Miyagi (JP); Yasuo Kobayashi, Miyagi (JP); Takehisa Saito, Miyagi (JP)

(73) Assignee: TOKYO ELECTRON LIMITED, Tokyo (JP)

(21) Appl. No.: 14/424,483

(22) PCT Filed: Jun. 18, 2013
(86) PCT No.: PCT/JP2013/066648

§ 371 Date: Feb. 27, 2015

(30) Foreign Application Priority Data
Sep. 3, 2012 (JP) 2012-192961

(51) Int. Cl. H01J 37/32

(52) U.S. Cl. CPC H01J 37/32779; H01J 37/3222; H01J 37/32724; H01J 37/32697; H01J 37/32743; H01J 37/32788; H01J 37/32834; H01J 37/32513

(57) ABSTRACT

Provided is a plasma processing apparatus including: a rotary mounting table supported by a rotatory shaft arranged rotatably within a processing chamber and including multiple substrate placement units arranged side by side in a circumferential direction; a processing gas supplying section for supplying processing gas into the processing chamber; a plasma generating section wherein multiple microwave introducing mechanisms, each provided on the ceiling of the processing chamber so as to face the rotary mounting table and used for generating a plasma of the processing gas, are arranged in multiple rows spaced apart from each other from the inside of the movement path of the substrates when the rotary mounting table is rotated to the outside, each row of microwave introducing mechanisms being formed by arranging the microwave introducing mechanisms annularly side by side along the circumferential direction; and an exhaust unit that evacuates an inside of the processing chamber.

### TECHNICAL FIELD

The present disclosure relates to a plasma processing apparatus that places and processes a plurality of processing target substrates such as, for example, semiconductor wafers or liquid crystal substrates within a processing chamber, and a substrate processing apparatus provided with the plasma processing apparatus.

### BACKGROUND

As a plasma processing apparatus of this type, a plasma processing apparatus has been developed in which a rotary mounting table (rotary table) is provided within a processing chamber to mount a plurality of semiconductor wafers (simply referred to as “wafers”) along a circumferential direction of the rotary table, and to perform a processing such as, for example, film formation, on each wafer while rotating the rotary mounting table (e.g., see Patent Document 1). Such a so-called semi-batch type plasma processing apparatus may process a plurality of wafers simultaneously, and thus, improve throughput as compared to a single type plasma processing apparatus that processes wafers one by one.

### PRIOR ART DOCUMENT

### Patent Document

Patent Document 1: Japanese Patent Laid-Open Publication No. 2011-151343

### SUMMARY OF THE INVENTION

### Problems to be Solved

However, when the rotary mounting table is rotated in such a semi-batch type plasma processing apparatus, the movement path of wafers draws a smaller circle at the center side of the rotary mounting table and a larger circle at the peripheral edge side of the rotary mounting table. Thus, even if the rotary mounting table is rotated at a constant speed, the circumferential speeds of respective portions on the surfaces of the wafers become equal to each other when the portions are equidistant from the center of the rotary mounting table. However, when the portions are not equidistant from the center of the rotary mounting table, the circumferential speeds of the portions do not become equal to each other. Specifically, on a wafer surface, a portion placed at a longer distance from the rotation center of the rotary mounting table moves more rapidly, and thus, a moving distance per unit time is also increased.

Thus, even if plasma is formed with uniform density on the entire surface of the rotary mounting table when it is desired to simultaneously perform a wafer processing over the rotary mounting table in the circumferential direction of the rotary mounting table, a contact time with the plasma is different between a portion near to the rotation center of the rotary mounting table and a portion far from the center of the rotary mounting table on each wafer surface, and as a result, the plasma processing is not uniformly performed from the inside to the outside of the movement path of the wafer.

Thus, the apparatus of Patent Document 1 adjusts the amount of plasma from the rotation center side to the peripheral edge side by adjusting the length of a plasma generation unit in the radial direction of the rotary mounting table. In the apparatus of Patent Document 1, however, the top side of the rotary mounting table is divided into a plurality of regions in the circumferential direction and different processings are performed on the regions, respectively. Thus, the plasma is only generated in some of the regions in the circumferential direction, and as a result, the plasma processing cannot be performed simultaneously on the respective wafers over the entire rotary mounting table in the circumferential direction of the rotary mounting table.

The present disclosure was made in consideration of the problems described above, and is to provide a plasma processing apparatus in which, when a plurality of substrates arranged on the rotary mounting table along the circumferential direction are simultaneously processed over the entire surface of the rotary mounting table, a plasma processing may be performed uniformly from the inside to the outside of the movement path of the substrates when the rotary mounting table is rotated.

### Means to Solve the Problems

In order to solve the problems described above, there is provided a plasma processing apparatus that performs a plasma processing on a plurality of substrates placed in a processing chamber. The plasma processing apparatus includes: a rotary mounting table supported by a rotatory shaft rotatably disposed within the processing chamber, and including a plurality of substrate placement units, which are arranged side by side in a circumferential direction to place the substrates thereon; a processing gas supplying section configured to supply a processing gas into the processing chamber; a plasma generating section provided on a ceiling of the processing chamber to face the rotary mounting table, and including a plurality of microwave introducing mechanisms configured to generate plasma of the processing gas, wherein the plurality of microwave introducing mechanisms are arranged in multiple rows which are spaced apart from each other from an area more inside than a movement path of the substrates when the rotary mounting table is rotated, to an area more outside than the movement path of the substrates, each row of the microwave introducing mechanisms being formed by arranging the microwave introducing mechanisms annularly side by side along the circumferential direction; and an exhaust unit configured evacuate an inside of the processing chamber.

In the present disclosure, since the plurality of microwave introducing mechanisms are arranged annularly side by side along the circumferential direction, the substrates may be processed simultaneously over the entire rotary mounting table in the circumferential direction. Thus, the time required for processing the substrates may be considerably reduced as compared to a case where plasma is generated in some regions. Furthermore, the plurality of microwave introducing mechanisms are disposed in multiple rows which are spaced apart from each other from an area more inside than the movement path of the substrates when the rotary mounting table is rotated to an area more outside than the movement path of the substrates, and thus the plasma processing may be adjusted to be uniform from the inside to the outside of the substrate movement path. As a result, the plasma processing may be performed uniformly from the inside to the outside of the substrate movement path while further enhancing the throughput of substrate processing.

The microwave introducing mechanisms may be arranged at regular intervals in the circumferential direction, and the rows may be arranged such that intervals between the rows are narrowed from the inside toward the outside. According to this, in the portions which are equidistant from the center of the rotary mounting table and thus are the same in a moving distance per unit time, plasma of the same plasma density may be generated, and in the portions which are different from each other in the moving distance per unit time, plasma may be generated such that the plasma density is increased as the distance from the center of the rotary mounting table is increased, i.e. as the moving distance per unit time is increased. As a result, the plasma processing uniformity can be enhanced from the inside to the outside of the substrate movement path.

The plurality of microwave introducing mechanisms may be arranged in three or more rows from the inside to the outside, the innermost row of the microwave introducing mechanisms may be arranged more inside than the movement path of the substrates, and the outermost row of the microwave introducing mechanisms is arranged more outside than the movement path of the substrates. In this case, the outermost row of the microwave introducing mechanisms may be spaced apart from the outermost side of the movement path of the substrates by a distance according to a distance between the microwave introducing mechanisms and the rotary mounting table. According to this, even if the plasma potential is varied in the vicinity of the side wall of the processing chamber, the potential-varied portion may be adjusted to an area more outside than the substrate movement path. Thus, the plasma potential on the substrates may be adjusted to be uniform. Meanwhile, the powers of the microwave introducing mechanisms may be set to be sequentially increased from the inside row to the outside row. According to this, the plasma density may also be adjusted from the inside to the outside of the substrate movement path, thereby improving the processing uniformity.

In addition, the processing gas supplying section may include a plurality of gas holes on the ceiling of the processing chamber to introduce the processing gas, in which the plurality of gas holes may be arranged in multiple rows spaced apart from each other from the inside of the movement path of the substrates to the outside of the movement path of the substrates, in which each row of the gas holes is formed by arranging the gas holes annularly side by side along the circumferential direction. In addition, a flow rate of the gas supplied from the gas holes may be adapted to be adjusted for each row. Further, the rotary mounting table may be formed with through holes along the circumferential direction more inside than the movement path of the substrates, the processing gas passing through the through holes. According to this, by adjusting a distance the gas holes in each row, the plasma processing uniformity may be enhanced from the inside to the outside of the substrate movement path.

In addition, each of the substrate placement units may include an electrostatic chuck configured to electrostatically attract a substrate, and the electrostatic chuck may include an electrode plate within an insulator. The electrostatic chuck may be configured such that both of a DC voltage for electrostatically attracting the substrate and a high frequency power for bias for applying a high frequency bias to the substrate are applicable to the electrode plate. In this case, for example, a terminal may be provided on the rotary shaft of the rotary mounting table to be electrically connected to an electrode of each of the substrate placement units so that the DC voltage and the high frequency power for bias may be fed to the terminal of the rotary shaft side while the rotary mounting table is rotated. According to this, the DC voltage or the high frequency power for bias may be always applied even if the rotary mounting table is being rotated.

In addition, a heat transfer gas may be supplied to a gap between each of the substrate placement units and the substrate placed on each of the substrate placement units. In this case, for example, a heat transfer gas inlet recess may be provided around the rotary shaft of the rotary mounting table so that the heat transfer gas may be supplied to the heat transfer gas inlet recess while the rotary mounting table is being rotated. According to this, the heat transfer gas may be always supplied while rotating the rotary mounting table.

In addition, a cooling mechanism configured to cool the substrate may be provided below the electrostatic chuck of each of the substrate placement units, and the cooling mechanism may be configured to circulate a coolant in a coolant flow path provided in a conductive member. In this case, for example, a coolant inlet recess and a coolant outlet recess may be provided around the rotary shaft of the rotary mounting table to communicate with the coolant flow path, in which the coolant inlet recess and the coolant outlet recess may be configured such that the coolant is introduced from the coolant inlet recess and led out from the coolant outlet recess while the rotary mounting table is rotated. According to this, the coolant may always be flowed through the coolant flow path so as to cool the substrates even if the rotary mounting table is being rotated.

In addition, each substrate placement unit of the rotary mounting table may be provided with a through hole through the substrate placement unit and the rotary mounting table to insert a lifter pin configured to raise the substrate from a lower side of the substrate, through the through hole so as to raise or lower the substrate with respect to the substrate placement unit. The lifter pin may be put into/out from the through hole from/to a lower side of the through hole by a lifter mechanism provided on a bottom portion of the processing chamber to be spaced apart from the rotary mounting table. In this case, the lifter mechanism may be configured to lift the lifter pin by a magnetic fluid actuator, and the lifter pin may be sealed by a magnetic fluid seal. According to this, the substrate may be raised or lowered by the lifter pin without interfering with the rotating movement of the rotary mounting table.

In addition, when the rotary mounting table is made of an insulating material, a heater configured to heat the substrate may be disposed within the rotary mounting table below the electrostatic chuck of each of the substrate placement units, and when the rotary mounting table is made of a conductive material, a heater configured to heat the substrate may be disposed below the electrostatic chuck of each of the substrate placement units through a ground member having a ground potential. In this case, a plurality of heaters may be arranged along the circumferential direction of each of the substrate placement units from the inside to the outside. In addition, a heater may be disposed to be spaced downwardly apart from the rotary mounting table and provided to heat the rotary mounting table from a lower side. According to this, even if a high frequency power for bias is applied while heating the substrates by the heaters, leakage of the high frequency power for bias to the heaters may be prevented.

In order to solve the problems described above, there is provided a substrate processing apparatus provided with a vacuum conveyance chamber which is connected with a plasma processing apparatus that performs a plasma processing on a plurality of substrates disposed within a processing chamber. The plasma processing apparatus includes: a rotary mounting table supported by a rotatory shaft rotatably disposed within the processing chamber, and including a plurality of substrate placement units, which are arranged side by side in a circumferential direction to place the substrates thereon; a processing gas supplying section configured to supply a processing gas into the processing chamber; a plasma generating section provided on a ceiling of the processing chamber to face the rotary mounting table, and including a plurality of microwave introducing mechanisms configured to generate plasma of the processing gas, wherein the plurality of microwave introducing mechanisms are arranged in multiple rows which are spaced apart from each other from an area more inside than a movement path of the substrates when the rotary mounting table is rotated to an area more outside than the movement path of the substrates, each row of the microwave introducing mechanisms being formed by arranging the microwave introducing mechanisms annularly side by side along the circumferential direction; and an exhaust unit configured evacuate an inside of the processing chamber. The vacuum conveyance chamber is connected with the plasma processing apparatus via a buffer chamber, and the buffer chamber is configured to temporarily accommodate the substrates which are equal to or more than a number to be capable of being placed on the rotary mounting table of the plasma processing apparatus.

According to the present disclosure described above, when a plurality of substrates to be processed subsequently are carried into and placed in the buffer chamber while the plasma processing is being performed in the plasma processing apparatus, only the delivery of the next substrates between the rotary mounting table and the buffer chamber is required when the next substrates are set on the rotary mounting table. Thus, the carry-in/out time of substrates may be considerably reduced.

In addition, the substrates accommodated in the buffer chamber may be carried out/in with respect to the vacuum conveyance chamber by a first conveyance arm apparatus provided in the vacuum conveyance chamber, and carried out/in with respect to the plasma processing apparatus by a second conveyance arm apparatus which is provided separately from the first conveyance arm apparatus. In addition, the second conveyance arm apparatus may be provided in a hermetically sealed chamber connected between the buffer chamber and the plasma processing apparatus. According to this, the delivery of the substrates between the plasma processing apparatus and the buffer chamber may be wholly performed by the second conveyance arm apparatus. Thus, the whole substrate conveyance throughput may be enhanced.

### Effect of the Invention

According to the present disclosure, when a plurality of substrates arranged on the rotary mounting table along the circumferential direction are simultaneously processed over the entire surface of the rotary mounting table, a plasma processing may be performed uniformly from the inside to the outside of the movement path of the substrates as the rotary mounting table is being rotated.

### BRIEF DESCRIPTION OF DRAWINGS

FIG. 1 is a vertical cross-sectional view illustrating an exemplary configuration of a plasma processing apparatus according to an exemplary embodiment of the present disclosure.

FIG. 2 is a plan view of a plasma generating section illustrated in FIG. 1.

FIG. 3 is a plan view of a rotary mounting table illustrated in FIG. 1.

FIG. 4 is a block diagram illustrating a configuration of the plasma generating section illustrated in FIG. 1.

FIG. 5 is a block diagram illustrating an exemplary configuration of a main amplifier illustrated in FIG. 4.

FIG. 6 is a vertical cross-sectional view illustrating an exemplary configuration of a microwave introducing mechanism illustrated in FIG. 1.

FIG. 7 is a view for describing an exemplary arrangement of microwave introducing mechanisms in the present exemplary embodiment, in which a part of the top surface of the plasma generating section is illustrated.

FIG. 8 is a view for describing an exemplary arrangement of microwave introducing mechanisms in the present exemplary embodiment, in which a part of the vertical cross-section of the plasma processing apparatus is illustrated.

FIG. 9 is a view illustrating an exemplary configuration of heaters to be applied to the plasma processing apparatus of the present exemplary embodiment.

FIG. 10 is a view for describing an exemplary arrangement of the heaters illustrated in FIG. 9.

FIG. 11 is a view illustrating another exemplary configuration of heaters to be applied to the plasma processing apparatus of the present exemplary embodiment.

FIG. 12 is a view for describing an exemplary arrangement of the heaters of FIG. 11.

FIG. 13 is a view for describing another exemplary configuration of a processing gas supplying section in the present exemplary embodiment in which an exemplary arrangement of gas holes is illustrated.

FIG. 14 is a cross-sectional view illustrating an exemplary configuration of a plasma processing apparatus to which the processing gas supplying section illustrated in FIG. 13 is applied.

FIG. 15 is a view for describing a configuration for forming processing gas flows in a direction toward the center of the rotary mounting table in the present exemplary embodiment.

FIG. 16 is a plan view of the rotary mounting table illustrated in FIG. 15.

FIG. 17 is a view for describing a modified example of the configuration for forming processing gas flows in a direction toward the center of the rotary mounting table in the present exemplary embodiment.

FIG. 18 is a plan view of the rotary mounting table illustrated in FIG. 17.

FIG. 19 is a vertical cross-sectional view illustrating another exemplary configuration of the rotary mounting table illustrated in FIG. 1.

FIG. 20 is a vertical cross-sectional view illustrating an exemplary configuration in a case where heaters are provided on the rotary mounting table illustrated in FIG. 19.

FIG. 21 is a vertical cross-sectional view illustrating another exemplary configuration of the plasma generating section illustrated in FIG. 1.

FIG. 22 is a plan view of the plasma generating section illustrated in FIG. 21.

FIG. 23 is a plan view of the rotary mounting table illustrated in FIG. 21.

FIG. 24 is a horizontal cross-sectional view illustrating an exemplary configuration of a substrate processing apparatus provided with the plasma processing apparatus according to the present exemplary embodiment.

FIG. 25 is a vertical cross-sectional view illustrating an exemplary configuration of the substrate processing apparatus illustrated in FIG. 24.

FIG. 26 is a vertical cross-sectional view illustrating an exemplary configuration of a lifter mechanism illustrated in FIG. 25.

FIG. 27A is an explanatory view illustrating an operation when wafers are set on the rotary mounting table using the lifter mechanism in the present exemplary embodiment.

FIG. 27B is an exemplary view illustrating an operation following FIG. 27A.

FIG. 27C is an exemplary view illustrating an operation following FIG. 27B.

FIG. 27D is an exemplary view illustrating an operation following FIG. 27C.

### DETAILED DESCRIPTION TO EXECUTE THE INVENTION

Hereinafter, exemplary embodiments of the present disclosure will be described in detail with reference to the accompanying drawings. In the specification and drawings, components having substantially the same configuration and function will be given the same symbols, and redundant descriptions will be omitted.

(Plasma Processing Apparatus)

First, an exemplary configuration of a plasma processing apparatus according to an exemplary embodiment of the present disclosure will be described with reference to the drawings. Here, descriptions will be made on a semi-batch type plasma processing apparatus in which surface wave plasma is generated within a processing chamber by a plurality of microwave introducing mechanisms so as to perform a plasma processing such as, for example, etching or film formation, on a plurality of wafers W on a rotary mounting table, as an example.

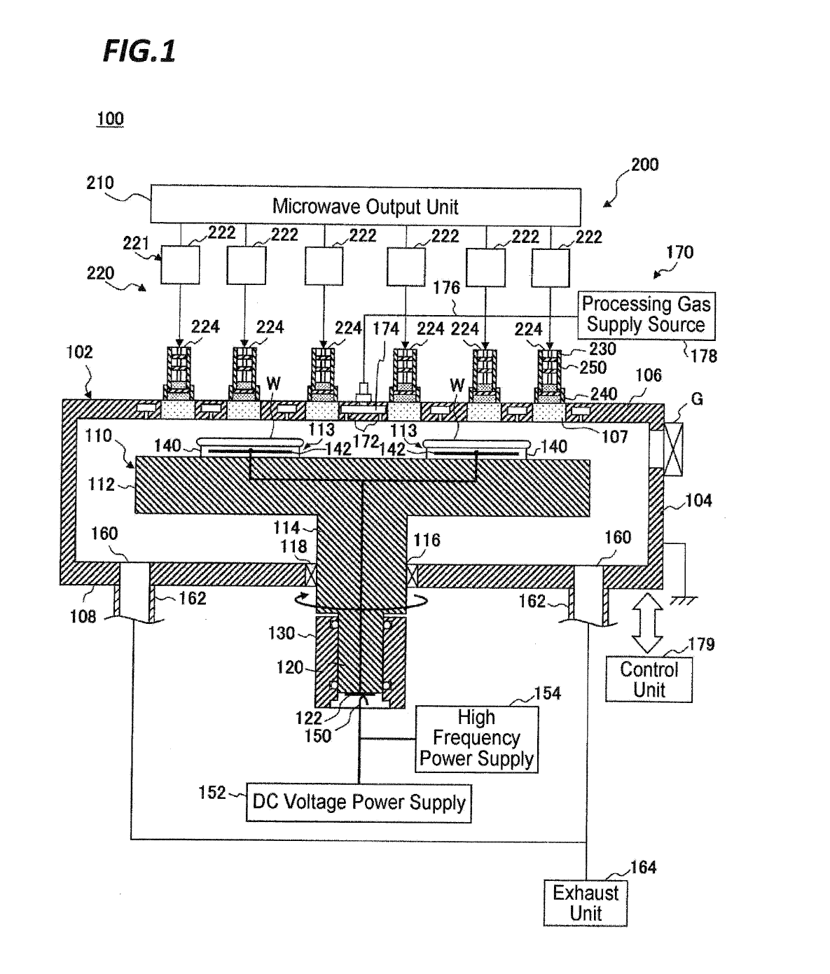

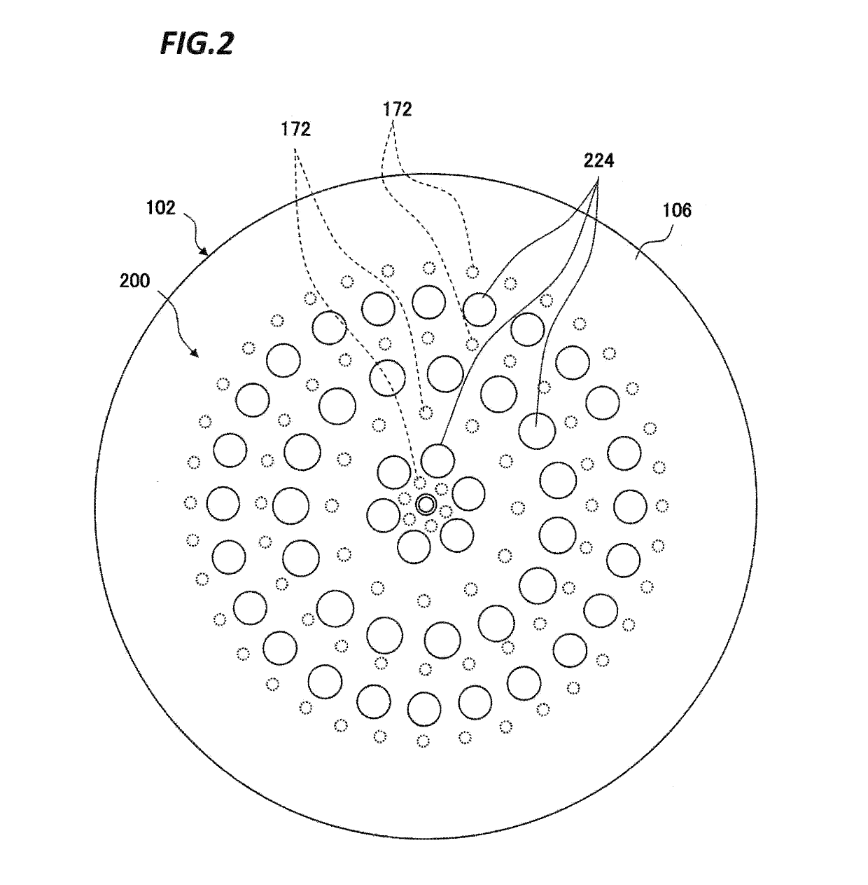

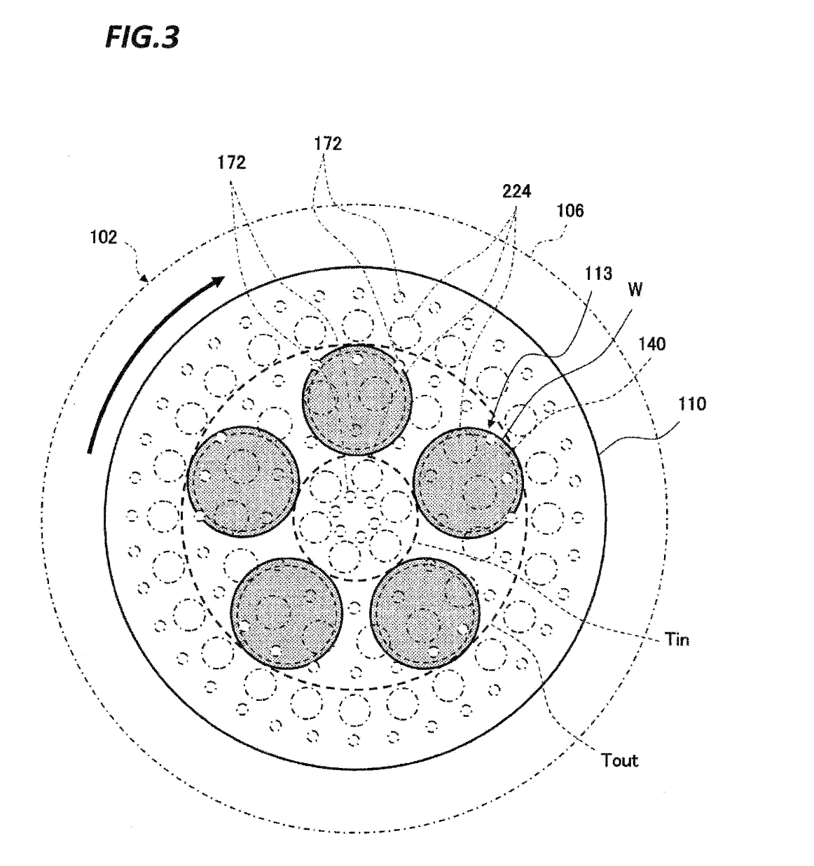

FIG. 1 is a cross-sectional view illustrating a schematic configuration of a semi-batch type plasma processing apparatus according to an exemplary embodiment of the present disclosure. FIG. 2 is a plan view of a plasma generating section illustrated in FIG. 1. FIG. 3 is a plan view of a rotary mounting table illustrated in FIG. 1. Meanwhile, in FIG. 2, the positions of gas holes 172 are indicated by dotted lines, and in FIG. 3, the positions of the gas holes 172 and microwave introducing mechanisms 224 arranged on the rotary mounting table 110 are indicated by one-dot chain lines, and the movement path of the wafers W (inside and outside of the movement path) when the rotary mounting table 110 is rotated are indicated by dotted lines.

As illustrated in FIG. 1, the plasma processing apparatus 100 is provided with a processing chamber 102 which is made of a conductive material such as, for example, aluminum. The processing chamber 102 is configured as an airtight processing container which includes a cylindrical side wall 104 having an opening in the top portion thereof, a disc-shaped ceiling 106, and a disc-shaped bottom portion 108. The ceiling 106 may be removably attached by fastening members such as, for example, bolts. The processing chamber 102 is earthed to a ground. Meanwhile, the shape of the processing chamber 102 is not limited to the cylindrical shape. For example, the shape of the processing chamber 102 may be an angular cylinder shape (e.g., a box shape).

A rotary mounting table 110 is rotatably installed within the processing chamber 102. Here, descriptions will be made on a case where the entire rotary mounting table 110 is made of an insulation member such as, for example, ceramic, as an example. The rotary mounting table 110 is provided with a disc-shaped rotary table 112, on which a plurality of (here, five) wafers W are mounted in the circumferential direction, and a rotary shaft 114 configured to support the rotary table 112 at the center of the rotary table 112.

The rotary shaft 114 rotatably penetrates a through hole 116 formed substantially at the center of the bottom portion 108 of the processing chamber 102. In the through hole 116, a seal member 118 such as, for example, an O-ring is provided between the bottom portion 108 and the rotary shaft 114 so as to maintain the airtightness of the inside of the processing chamber 102. Meanwhile, the seal member 118 is not limited to the O-ring. The seal member 118 may be configured by a magnetic fluid seal so as to reduce, for example, occurrence of particles.

The lower end portion 120 of the rotary shaft 114 is inserted into a mounting table driving unit 130. The mounting table driving unit 130 includes, for example, a motor, and is configured to rotate the rotary shaft 114 in a predetermined direction, for example, clockwise. The lower end of the mounting table driving unit 130 is opened so that a power feeding terminal 122 provided on the bottom surface of the lower end portion 120 of the rotary shaft 114 is exposed downwardly. Thus, when a power required for the rotary mounting table 110, for example, a direct current (DC) voltage for electrostatic attraction of a wafer W (described below) is supplied, a power feeding brush 150 connected to the power supply is always in contact with the power feeding terminal 122 so that the required power may be fed to the power feeding terminal even during the rotation of the rotary mounting table 110.

On the rotary table 112, wafer placement units 113 are arranged in the circumferential direction in which wafers W are placed on the wafer placement units 113, respectively. The number of wafer placement units 113 to be provided may correspond to the number of wafers which may be processed at once. When five wafers W are processed at once as in the present exemplary embodiment, five wafer placement units 113 are arranged at regular intervals along the circumferential direction, as illustrated in FIG. 3. Meanwhile, the number of the wafer placement units 113 is not limited to that illustrated in the drawing.

An electrostatic chuck 140 is provided on each of the wafer placement units of the rotary table 112 to hold a wafer W through electrostatic attraction. Each of the electrostatic chucks 140 illustrated in FIG. 1 is attached to the top surface of the rotary table 112, and may be configured, for example, by interposing an electrode 142 made of a conductive film such as, for example, a copper foil, between, for example, two high-molecular polyimide films or ceramics in an insulation state. The wafer W may be attracted and held on the electrostatic chuck 140 by a Coulomb force generated when the DC voltage is applied to the electrode 142.

In the present exemplary embodiment, the electrode 142 of each electrostatic chuck 140 is configured such that a high frequency power for bias may be applied thereto when a plasma processing is performed, besides the DC voltage for electrostatic attraction. Specifically, the electrode 142 of each electrostatic chuck 140 is connected to the power feeding terminal 122 via a wiring within the rotary mounting table 110. In addition, the power feeding brush 150 which is in contact with the power feeding terminal 122 is connected with both of a DC voltage power supply 152 configured to supply the DC voltage for electrostatic attraction and a high frequency power supply 154 configured to supply the high frequency power for bias. Thus, since the wafer W may be electrostatically attracted and the high frequency bias may be applied to the wafer W, a processing rate of the plasma processing can be enhanced and in-plane uniformity can also be improved.

Meanwhile, the DC voltage power supply 152 may be provided with a filter (not illustrated) in order to prevent the leakage of the high frequency power for bias. In addition, in a case where the entire rotary table 112 is made of an insulation material, a heater made of a resistance heating element may be installed to heat the wafer W as described below. In such a case, when the heater is installed on the rotary table 112 below the electrostatic chuck 140, the leakage of the high frequency power for bias to the heater may be prevented.

A gate valve G is provided on the side wall 104 of the processing chamber 102 to open/close a wafer carry-in/out port. In addition, a plurality of exhaust ports 160 are provided on the bottom portion 108 of the processing chamber 102 along the circumferential direction of the rotary mounting table 110. Each of the exhaust ports 160 is connected with an exhaust unit 164 including a vacuum pump (not illustrated) through an exhaust pipe 162. When the inside of the processing chamber 102 is evacuated by the exhaust unit 164, the inside of the processing chamber 102 may be maintained at a predetermined vacuum atmosphere during the plasma processing.

A processing gas supplying section 170 configured to supply a predetermined processing gas into the processing chamber 102, and a plasma generating section 200 configured to form plasma of the processing gas within the processing chamber 102 are disposed on the ceiling 106 of the processing chamber 102. Here, the plasma generating section 200 functions as a microwave plasma source since it generates microwave plasma.

The processing gas supplying section 170 herein includes a plurality of gas holes 172 formed in the ceiling 106 and thus, is configured to supply the processing gas in a shower state. The gas holes 172 communicate with a gas flow path 174 formed in the inside of the ceiling 106. The gas flow path 174 is connected with a processing gas supply source 178 through a pipe 176. The flow rate of the processing gas from the processing gas supply source 178 is controlled to a predetermined flow rate by a flow control unit such as, for example, a mass flow controller (MFC) (not illustrated) when the processing gas is supplied to the gas flow path 174.

Thus, since the processing gas such as, for example, Ar gas may be ejected uniformly from the gas holes 172, the processing gas may be rapidly turned into plasma so that uniform plasma can be generated. For example, as illustrated in FIG. 2, the gas holes 172 are arranged in multiple rows from the center side to the peripheral edge side of the ceiling 106, in which each row of the gas holes 172 is formed by arranging side by side the gas holes 172 annularly along the circumferential direction of the ceiling 106. FIG. 2 illustrates an example in which the gas holes 172 are arranged annularly in four rows. Meanwhile, the number of the gas holes 172 and the number of rows are not limited to those illustrated in the drawing.

(Exemplary Configuration of Plasma Generating Section)

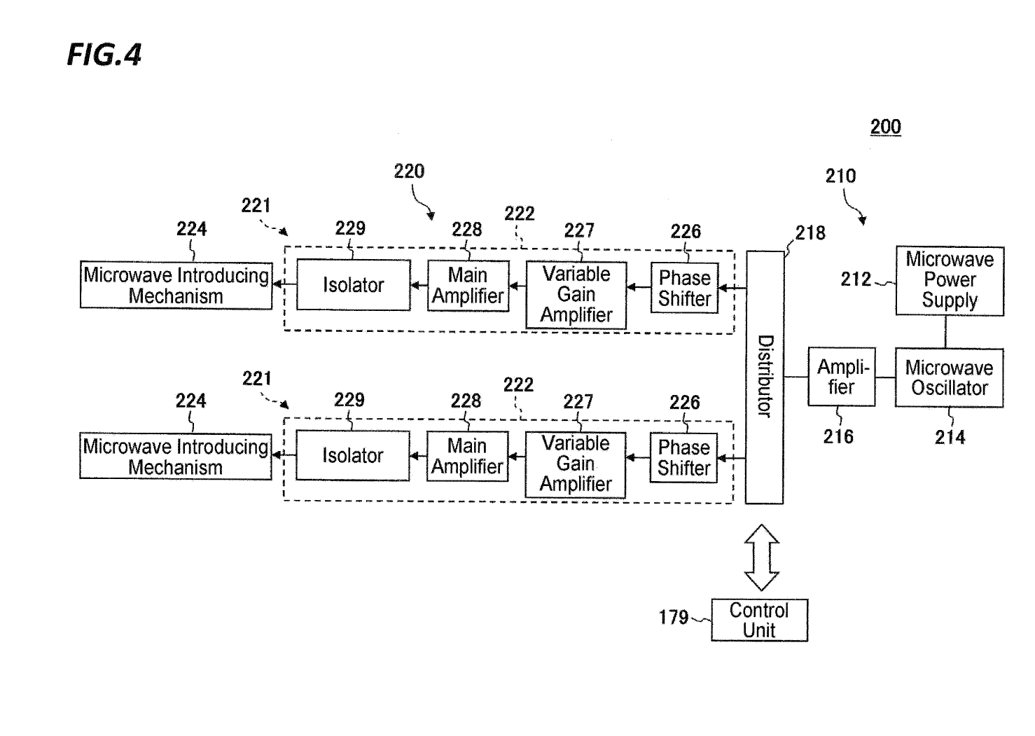

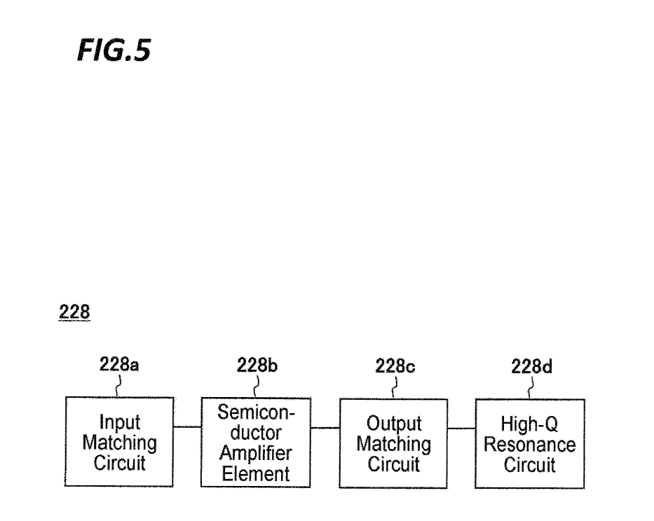

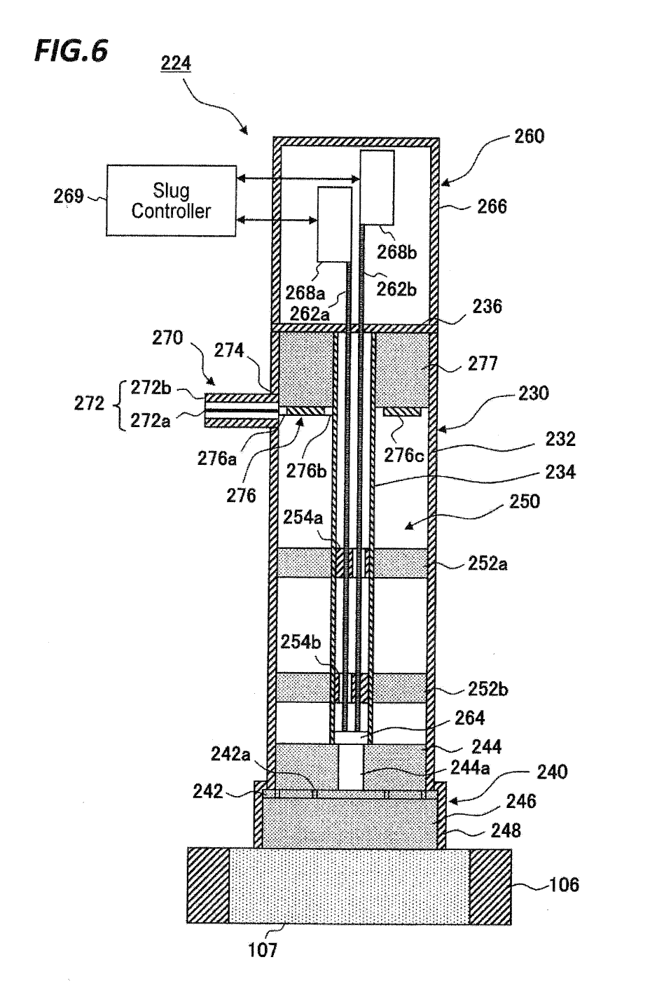

Now, an exemplary configuration of the plasma generating section 200 illustrated in FIG. 1 will be described with reference to drawings. Here, descriptions will be made on the plasma generating section 200 which includes a plurality of microwave introducing mechanisms provided on the ceiling 106 of the processing chamber 102 to generate microwave plasma within the processing chamber 102, as an example. FIG. 4 is a block diagram illustrating a configuration of a plasma generating section illustrated in FIG. 1. FIG. 5 is a block diagram illustrating an exemplary configuration of a main amplifier illustrated in FIG. 4. FIG. 6 is a cross-sectional view illustrating an exemplary configuration of a microwave introducing mechanism illustrated in FIG. 1.

As illustrated in FIG. 1, the plasma generating section 200 in the present exemplary embodiment is provided to face the inside of the processing chamber 102 at the top opening of the processing chamber 102. Here, the plasma generating section 200 includes a microwave output unit 210 configured to output microwaves to be distributed to a plurality of paths, and a microwave supply unit 220 configured to guide the microwaves output from the microwave output unit 210 into the processing chamber 102 and to radiate the microwaves into the processing chamber 102.

As illustrated in FIG. 4, the microwave output unit 210 includes a microwave power supply 212, a microwave oscillator 214, an amplifier 216 configured to amplify oscillated microwaves, and a distributor 218 configured to distribute amplified microwaves to the plurality of paths.

The microwave oscillator 214 oscillates microwaves having a predetermined frequency (e.g., 2.45 GHz), for example, in a PLL oscillation mode. The distributor 218 distributes the microwaves amplified by the amplifier 216 while matching the impedances of the input and output sides so that loss of microwaves is not caused if possible. As the frequencies of microwaves, for example, 8.35 GHz, 5.8 GHz, 1.98 GHz, and 915 MHz may be used, besides 2.45 GHz.

The microwave supply unit 220 includes a plurality of antenna modules 221 so as to guide the microwaves distributed by the distributer 218 into the processing chamber 102. Each antenna module 221 is provided with an amplifier unit 222 configured to mainly amplify the distributed microwaves, and a microwave introducing mechanism 224.

As illustrated in FIG. 1, each microwave introducing mechanism 224 is generally divided into a waveguide 230 having a coaxial structure and configured to transmit microwaves, and an antenna unit 240 configured to radiate the microwaves transmitted from the waveguide 230 into the processing chamber 102. A tuner 250 configured to match load (plasma) impedances within the processing chamber 102 is provided within the waveguide 230.

Each microwave introducing mechanism 224 is disposed on the ceiling 106. The ceiling 106 is provided with a dielectric member 107 at a position where each microwave introducing mechanism 224 is disposed, in which the dielectric member 107 is made of a dielectric material such as, for example, quartz. Thus, the ceiling 106 may serve as a microwave transmission plate. A specific exemplary configuration of each microwave introducing mechanism 224 will be described below.

In consideration of efficiency or in-plane uniformity when each wafer W is subjected to a plasma processing while the rotary mounting table 110 is rotated, the microwave introducing mechanisms 224 are arranged in multiple rows spaced apart from each other from an area more inside than the movement path of the wafers W to an area more outside than the movement path of the wafers W, in which each row of the microwave introducing mechanisms 224 is formed by arranging side by side the microwave introducing mechanisms 224 annularly along the circumferential direction of the rotary mounting table 110, for example, as illustrated in FIG. 3.

Since the plurality of microwave introducing mechanisms 224 are arranged side by side annularly along the circumferential direction, the wafers W may be simultaneously processed over the entire rotary mounting table 110 along the circumferential direction of the rotary mounting table 110 so that the time required for processing the wafers W may be greatly reduced as compared to a case where plasma is formed in some regions.

In addition, since the plurality of microwave introducing mechanisms 224 are arranged in multiple rows to be spaced apart from each other from an area more inside than the movement path of the wafers W to an area more outside than the movement path of the wafers W when the rotary mounting table 110 is rotated, the plasma processing may be adjusted to be uniformly performed from the inside to the outside of the movement path of the wafers W. As a result, the plasma processing may be uniformly performed from the inside to the outside of the movement path of the wafers W while improving the wafer processing throughput. Meanwhile, the number of the microwave introducing mechanisms 224 and the number of rows of the microwave introducing mechanisms 224 are not limited to those illustrated in the drawing. Details for an arrangement of respective microwave introducing mechanisms 224 will be described in detail below.

When microwaves are radiated to the inside of the processing chamber 102 from the antenna unit 240 of each of the microwave introducing mechanisms 224, the microwaves are combined in the space within the processing chamber 102 so that surface wave plasma is formed within the processing chamber 102.

For example, as illustrated in FIG. 4, the amplifier unit 222 of each antenna module 221 includes a phase shifter 226, a variable gain amplifier 227, a main amplifier 228 that constitutes a solid state amplifier, and an isolator 229. The phase shifter 226 herein is configured to be capable of changing the phase of microwaves, and a radiation characteristic may be modulated by adjusting the phase shifter 226. For example, directivity may be controlled to vary a plasma distribution by adjusting a phase for each antenna module.

The variable gain amplifier 227 is an amplifier that adjusts a power level of microwaves input to the main amplifier 228, and adjusts variation of each antenna module or adjusts plasma intensity. When the variable gain amplifier 227 is varied for each antenna module, a distribution may occur in the generated plasma.

For example, as illustrated in FIG. 5, the main amplifier 228 herein may be configured as a solid state amplifier including an input matching circuit 228a, a semiconductor amplification element 228b, an output matching circuit 228c, and a high-Q resonance circuit 228d.

The isolator 229 is configured to separate reflected microwaves which are reflected from the antenna unit 240 and directed toward the main amplifier 228, and includes a circulator and a dummy load (coaxial terminator). The circulator guides the microwaves reflected from the antenna unit 240 to a dummy load which in turn coverts the reflected microwaves guided by the circulator into heat.

(Exemplary Configuration of Microwave Introducing Mechanism)

Next, a specific exemplary configuration of a microwave introducing mechanism 224 will be described with reference to the drawing. Here, descriptions will be made on a case where the microwave introducing mechanism 224 is configured to be fed with power from a side portion of a waveguide that transmits microwaves, as an example. FIG. 6 is a cross-sectional view illustrating a specific exemplary configuration of a microwave introducing mechanism in the present exemplary embodiment. Since all the microwave introducing mechanisms 224 are configured to be similar to each other, one microwave introducing mechanism 224 will be described representatively.

As illustrated in FIG. 6, the microwave introducing mechanism 224 includes a waveguide 230 having a coaxial structure and configured to transmit microwaves, and an antenna unit 240 configured to radiate microwaves transmitted through the waveguide 230 to the inside of the processing chamber 102. In addition, the microwaves radiated to the inside of the processing chamber 102 from the microwave introducing mechanism 224 are combined in the space within the processing chamber 102 so that surface wave plasma is formed within the processing chamber 102.

The waveguide 230 includes a cylindrical outer conductor 232 and a rod-shaped inner conductor 234 coaxially disposed at the center of the outer conductor 232, in which the antenna unit 240 is installed at the lower end (front end) of the waveguide 230. In the waveguide 230, the inner conductor 234 is the power feeding side, and the outer conductor 232 is the ground side. A reflector 236 is provided on the top ends (base ends) of the outer conductor 232 and the inner conductor 234.

A tuner 250 is provided within the waveguide 230 to match the impedance of the load (plasma) within the processing chamber 102 with a characteristic impedance of a microwave power supply in the microwave output unit 210. The tuner 250 includes two slugs 252a, 252b vertically arranged within the waveguide 230, and a slug driving unit 260 configured to slidably drive the slugs. Meanwhile, since the microwave introducing mechanism 224 in the present exemplary embodiment is configured to be fed with power from a side portion rather than from the top portion, the slug driving unit 260 may be provided outside (above) the reflector 236.

Each of the slugs 252a, 252b is made of an annular dielectric material installed between the outer conductor 232 and the inner conductor 234, and provided to be vertically slidable between the outer conductor 232 and the inner conductor 234. Specifically, the annular slugs 252a, 252b are respectively provided with slide members 254a, 254b at the central holes thereof in which the slide members 254a, 254b are made of a resin having a sliding property. The slide members 254a, 254b are placed inside the inner conductor 234 and include protrusions formed on the outer peripheries thereof to be inserted into a slit (not illustrated) formed in the longitudinal direction of the inner conductor 234 and to be supported on the inner peripheries of the annular slugs 252a, 252b. As a result, the slugs 252a, 252b are vertically slidable along the inner conductor 234.

In addition, the slide members 254a, 254b are respectively screw-coupled with slug moving shafts 262a, 262b which are installed within the inner space of the inner conductor 234 along the longitudinal direction thereof and include threads formed on the outer peripheries thereof. Specifically, a screw hole and a through hole are formed in each of the slide members 254a, 254b, in which the slug moving shaft 262a is screw-coupled to the screw hole of the slide member 254a and the slug moving shaft 262b is inserted through the through hole of the slide member 254a. The slug moving shaft 262b is screw-coupled to the screw hole of the other slide member 254b, and the slug moving shaft 262a is inserted through the through hole of the slide member 254b.

The slug moving shafts 262a, 262b are configured to be rotatably driven by the slug driving unit 260. Specifically, the slug moving shafts 262a, 262b extend to the slug driving unit 260 through the reflector 236. A bearing (not illustrated) is provided between the slug moving shafts 262a, 262b and the reflector 236. In addition, a bearing unit 264 made of a conductor is provided at the lower end of the inner conductor 234, and the lower ends of the slug moving shafts 262a, 262b are pivotally supported by the bearing unit 264. The slug driving unit 260 is provided with rotary driving units 268a, 268b within a housing 266 to rotate the slug moving shafts 262a, 262b, respectively, in which each of the rotary driving units 268a, 268b includes, for example, a motor or a gear. Meanwhile, encoders may be provided on the motors of the rotary driving units 268a, 268b, respectively, so that the positions of the slugs 252a, 252b may be detected by the encoders.

As a result, when the slug moving shaft 262a is rotated by the rotary driving unit 268a to slide the slide member 254a, only the slug 252a may be moved up and down, and when the slug moving shaft 262b is rotated by the rotary driving unit 268b to slide the slide member 254b, only the slug 252b may be moved up and down.

The positions of the slugs 252a, 252b are controlled by a slug controller 269. Specifically, based on an impedance value of an input end detected by an impedance detector (not illustrated) and position information of the slugs 252a, 252b detected by the encoders of the rotary driving units 268a, 268b, the slug controller 269 sends a control signal to the motors of the rotary driving units 268a, 268b to control the positions of the slugs 252a, 252b, thereby adjusting the impedance. The slug controller 269 executes impedance matching such that a termination becomes, for example, 50Ω. When only one of the two slugs 252a, 252b is moved, a trace passing through an origin of a Smith chart is drawn and when both slugs 252a, 252b are simultaneously moved, only the phase is rotated.

A power feeding mechanism 270 configured to feed microwaves (electromagnetic waves) is provided on a side surface of the waveguide 230 (outer conductor 232) at the base end side of the waveguide 230. The power feeding mechanism 270 includes a coaxial line 272 formed by an inner conductor 272a and an outer conductor 272b as a power feeding line for supplying microwaves amplified by the amplifier unit 222. The coaxial line 272 is connected to a microwave power inlet port 274 provided on the side surface of the outer conductor 232 of the waveguide 230, and the front end of the inner conductor 272a of the coaxial line 272 is connected with a power feeding antenna 276 extending horizontally toward the inside of the outer conductor 232 of the waveguide 230.

The power feeding antenna 276 is formed, for example, as a microstrip line on a printed circuit board (PCB). A slow wave material 277 is provided between the reflector 236 and the power feeding antenna 276, in which the slow wave material 277 is made of a dielectric material such as, for example, Teflon (registered mark) to shorten an effective wavelength of reflected waves. Meanwhile, when microwaves having a high frequency such as, for example, 2.45 G, are used, the slow wave material 277 may not be provided. At this time, when the electromagnetic waves radiated from the power feeding antenna 276 are reflected by the reflector 236, maximum electromagnetic waves are transmitted to the inside of the waveguide 230 of the coaxial structure. In such a case, the distance from the power feeding antenna 276 to the reflector 236 is set to be about λg/4 multiplied by one half-wavelength.

The power feeding antenna 276 includes, for example, an antenna body, which is provided with a first pole 276a which is connected with the inner conductor 272a of the coaxial line 272 in the microwave power inlet port 274 to be supplied with electromagnetic waves and a second pole 276b which is in contact with the inner conductor 234 of the waveguide 230 to radiate electromagnetic waves supplied from the first electrode 276a, and a ring-shaped reflection unit 276c extending along the outside of the inner conductor 234 of the waveguide 230 from the opposite sides of the antenna body. The power feeding antenna 276 is configured to form standing waves with the electromagnetic waves incident on the antenna body and the electromagnetic waves reflected from the reflection unit 276c.

When the power feeding antenna 276 radiates the microwaves (electromagnetic waves), a microwave power is fed to the space between the outer conductor 232 and the inner conductor 234 of the waveguide 230. In addition, the microwave power fed to the power feeding mechanism 270 is propagated toward the antenna unit 240.

The antenna unit 240 is configured to function as a microwave radiation antenna. Specifically, the antenna unit 240 is provided with a planar slot antenna 242 having slots 242a and a slow wave material 244 provided on the top of the planar slot antenna 242. A columnar member 244a formed of a conductor penetrates the center of the slow wave material 244 so as to connect the bearing unit 264 and the planar slot antenna 242 with each other. Thus, the inner conductor 234 is connected to the planar slot antenna 242 through the bearing unit 264 and the columnar member 244a.

A slow wave material 246 is disposed at the front end side (lower end side) of the planar slot antenna 242. Meanwhile, the lower end of the outer conductor 232 extends to the planar slot antenna 242 to cover the periphery of the slow wave material 244. In addition, the peripheries of the planar slot antenna 242 and the slow wave material 246 are covered with a coated conductor 248.

The slow wave materials 244, 246 have a dielectric constant larger than that of vacuum, and are made of, for example, quartz, ceramic, a fluorine-based resin such as, for example, polytetrafluoroethylene, or a polyimide-based resin. The wavelength of microwaves is lengthened within vacuum. Thus, when the slow wave materials 244, 246 are configured to have a dielectric coefficient larger than that of vacuum, the wavelength of microwaves may be shortened and the size of the antenna may be reduced.

In addition, the slow wave materials 244, 246 may adjust the phase of microwaves according to the thicknesses thereof which are adjusted so that the planar slot antenna 242 becomes an “antinode” of standing waves. In this way, the reflection may be minimized and the radiation energy of the planar slot antenna 242 may be maximized.

The slow wave material 246 of each microwave introducing mechanism 224 is provided to be in contact with the top surface of one of the dielectric members 107 formed in the ceiling 106. In addition, the microwaves amplified by the main amplifier 228 pass through the space between the peripheral walls of the inner conductor 234 and the outer conductor 232 and penetrate the slow wave material 246 and the dielectric member 107 of the ceiling 106 from the slots 242a of the planar slot antenna 242, thereby being radiated in the space within the processing chamber 102.

In the present exemplary embodiment, the main amplifier 228, the tuner 250, and the planar slot antenna 242 are arranged adjacent to each other. In addition, the tuner 250 and the planar slot antenna 242 constitute a lumped constant circuit existing within a ½ wavelength, and the planar slot antenna 242 and the slow wave materials 244, 246 have a combined resistance set to 50Ω. Thus, the tuner 250 may directly perform tuning on the plasma load, thereby efficiently transferring energy to the plasma.

Each component in the plasma processing apparatus 100 is adapted to be controlled by a control unit 179 provided with a microprocessor. The control unit 179 includes, for example, a storage unit in which a process sequence of the plasma processing apparatus 100 and process recipes as control parameters are stored, an input unit, and a display unit. The control unit 179 is configured to control the plasma processing apparatus according to a selected process recipe.

When a plasma processing is performed on wafers W in the plasma processing apparatus 100 configured as described above, five wafers W are carried into the processing chamber 102 one by one, and the wafers W are respectively placed on the electrostatic chucks 140 while rotating the rotary mounting table 110. A DC voltage is supplied to the electrostatic chucks 140 to electrostatically attract the wafers W.

When all the five wafers W are placed on the rotary mounting table 110, the plasma processing is initiated while rotating the rotary mounting table 110. That is, microwaves are introduced into the processing chamber 102 from the plasma generating section 200 while injecting, for example, an etching gas or a film forming gas from the processing gas supplying section 170 into the processing chamber 102, thereby generating surface wave plasma. As a result, the plasma processing is performed on all the wafers W.

When the surface wave plasma is generated, in the plasma generating section 200, the microwave power oscillated by the microwave oscillator 214 of the microwave output unit 210 is amplified by the amplifier 216 and then distributed into multiple microwave powers by the distributer 218, and the distributed microwave powers are guided to the microwave supply unit 220.

In the microwave supply unit 220, the multiple distributed microwave powers are respectively amplified by the main amplifiers 228, each constituting a solid state amplifier, and the distributed microwave powers are fed to the waveguides 230 of the microwave introducing mechanisms 224, respectively, and subjected to automatic impedance matching in the tuners 250. Then, substantially without power reflection, the distributed microwave powers are radiated into the processing chamber 102 through the slow wave materials 244, the planar slot antennas 242, the slow wave materials 246 of the antenna units 240, and the dielectric members 107 of the ceiling 106, and spatially combined in the processing chamber 102, thereby generating surface wave plasma.

In the present exemplary embodiment, since a plurality of wafers W are arranged along the circumferential direction of the rotary mounting table 110, the movement path of the wafers W when the rotary mounting table 110 is rotated becomes, for example, as illustrated in FIG. 3, an annular region between a circular trace drawn in the vicinity of a central portion, to which the distance from the center of the rotary mounting table 110 is shortest (an inner circle indicated by a one-dot chain line), and a circular trace drawn in the vicinity of the peripheral edge, to which the distance from the center of the rotary mounting table 110 is longest (an outer circle indicated by a one-dot chain line).

Thus, in the exemplary embodiment, for example, as illustrated in FIGS. 2 and 3, the microwave introducing mechanisms 224 are arranged in multiple rows which are spaced apart from each other from an area more inside than the movement path of the wafers W and to an area more outside than the movement path of the wafers W, in which each row is formed by arranging the microwave introducing mechanisms 224 side by side annularly along the circumferential direction of the rotary mounting table 110. FIGS. 2 and 3 illustrate an example in which the microwave introducing mechanisms 224 are arranged annularly in three rows.

When the microwave introducing mechanisms 224 are arranged annularly in multiple rows from the inside of the movement path of the wafers W to the outside of the movement path of the wafers W, plasma may be generated in the annular region where the wafers W pass when the rotary mounting table 110 is rotated. As a result, the plasma processing may be efficiently performed on each of the wafers W.

Further, when the microwave introducing mechanisms 224 are arranged in multiple rows from an area more inside than the movement path of the wafers W to an area more outside than the movement path of the wafers W, the in-plane uniformity of the plasma processing between radial portions from the center of the rotary mounting table 110 may be improved in each rotating wafer W. That is, since the plasma generated within the processing chamber 102 is warped in the vicinity of the side wall of the processing chamber 102, the microwave introducing mechanisms 224 may be arranged more outside than the movement path of the wafers W so that the plasma of each wafer W may be adjusted to become uniform.

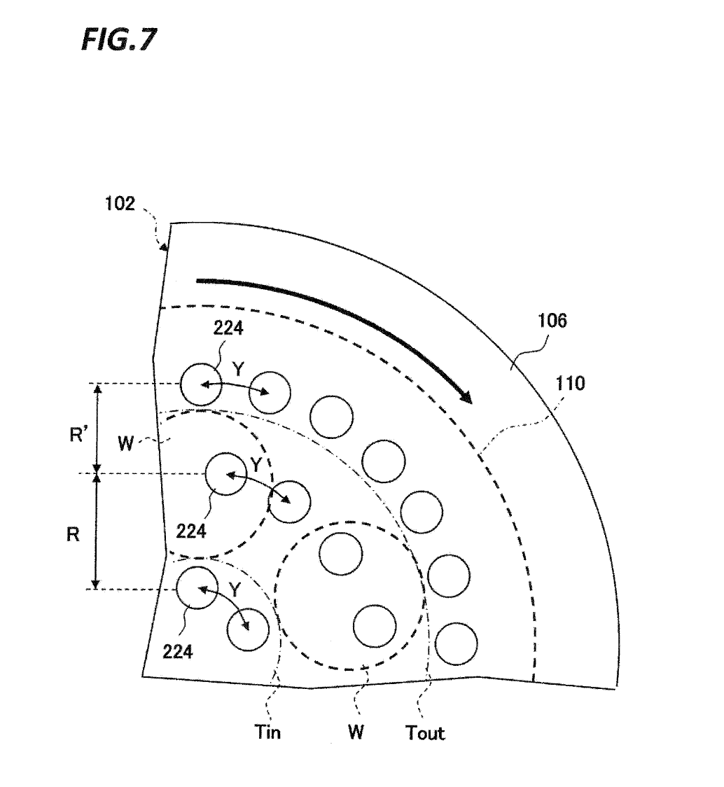

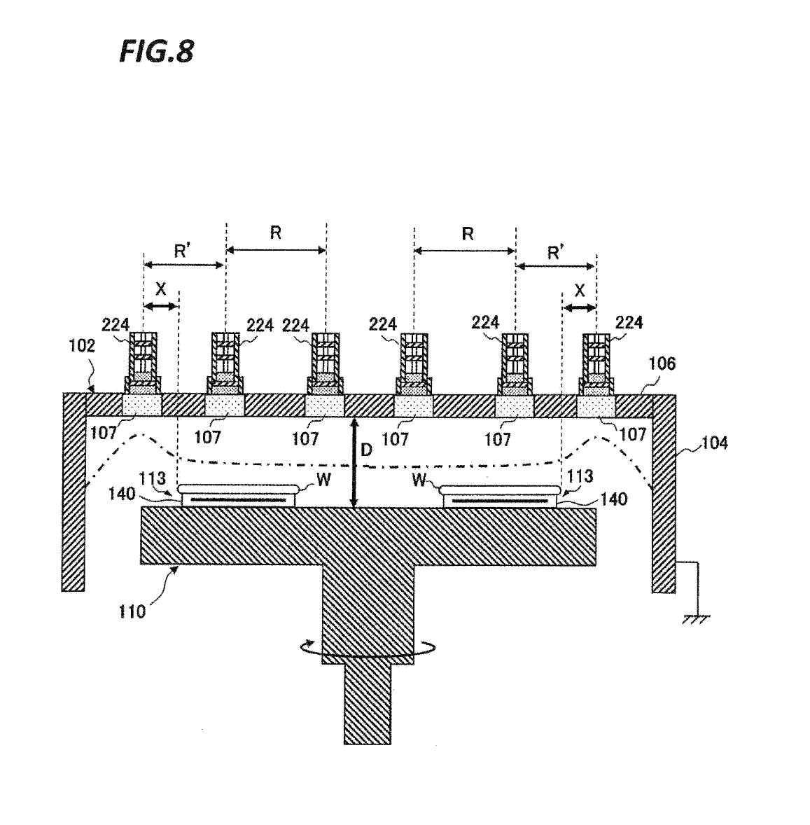

Here, the arrangement of the microwave introducing mechanisms 224 will be described in detail with reference to the drawings. Each of FIGS. 7 and 8 is a view for describing the arrangement of the microwave introducing mechanisms 224. Referring to FIG. 7, the rotary mounting table 110 and wafers W are depicted by dotted lines, and the movement path (inside and outside) of the wafers W when the rotary mounting table 110 is rotated is depicted by one-dot chain lines.

As illustrated in FIG. 7, the movement path of the wafers W when the rotary mounting table 110 is rotated draws a smaller circle at the center side of the rotary mounting table 110 and a larger circle at the peripheral edge side of the rotary mounting table 110. Thus, even if the rotary mounting table 110 is rotated at a constant speed, a plasma contact time of each point on the surface of each wafer W is varied depending on the distance from the center of the rotary mounting table 110. Specifically, on each wafer surface, the plasma contact time becomes longer as the distance from the center of the rotary mounting table 110 is shorter, and the plasma contact time becomes shorter as the distance from the center of the rotary mounting table 110 is longer.

For this reason, even if plasma having uniform density is formed on the movement path of the wafers W, the plasma contact time is varied between portions on each wafer surface, to which the distances from the center of the rotary mounting table 110 are different from each other, for example, between the center side (the inside of the movement path) and the peripheral edge side (the outside of the movement path) of the rotary mounting table 110. Thus, the plasma processing cannot be uniformly performed.

Thus, it is preferable that the microwave introducing mechanisms 224 are arranged at regular intervals Y in the circumferential direction and the intervals between the rows are reduced towards the outside from the inside of the movement path of the wafers W. For example, as illustrated in FIGS. 7 and 8, when the microwave introducing mechanisms 224 are arranged in three rows, the intervals L of the microwave introducing mechanisms 224 in each row in the circumferential direction are set to be equal to each other, and the distance R′ between the second row and the third row is set to be narrower than the distance R between the first row which is closest to the center of the rotary mounting table 110 and the second row.

Then, plasma may be generated in such a manner that the plasma density is equal in the circumferential direction at the portions to which the distances from the center of the rotary mounting table 110 are the same, and the plasma density is increased as the distance from the center of the rotary mounting table 110 is increased. As a result, in the wafers W, the processing uniformity may be enhanced not only in the circumferential direction of the rotary mounting table 110, but also in the radial direction.

When adjusting the power of each microwave introducing mechanism 224, it is preferable that the adjustment is performed such that the processing on the surfaces of the wafers W is uniformly performed in the radial direction of the rotary mounting table 110. Specifically, it is preferable that the adjustment is performed such that the plasma potential becomes substantially equal on the wafers W. Even with such adjustment, however, since the plasma potential becomes zero on the side wall 104 of the processing chamber 102 (ground potential), the variation of the plasma potential is increased in the vicinity of the side wall 104, as illustrated in FIG. 8 (the line indicated by a one-dot chain line). The magnitude of variation of the plasma potential in the vicinity of the side wall 104 is varied depending on the distance D between the plasma generating section 200 and the rotary mounting table 110. Specifically, the variation of the plasma potential in the vicinity of the side wall 104 increases as the distance D between the plasma generating section 200 and the rotary mounting table 110 increases.

Thus, the outside row closest to the side wall 104 among the rows of the microwave introducing mechanisms 224 is spaced apart from the outermost side in the movement path of the wafers W by a distance X according to the distance D between the plasma generating section 200 and the rotary mounting table 110. In such a case, the distance X between the outermost row of the microwave introducing mechanisms 224 and the outermost side of the movement path of the wafers W may be adjusted in a range of ¼ to ½ of the distance D between the plasma generating section 200 and the rotary mounting table 110. As a result, the portions close to the side wall 104 on the surfaces of the wafers W may also be set to have the same plasma potential as the central portions of the wafers W. The processing uniformity may be enhanced between the portions close to the side wall 104 and the central portions on the surfaces of the wafers W. Meanwhile, concerning the innermost row among the rows of the microwave introducing mechanisms 224, the plasma potential at the center side of the rotary mounting table 110 may be adjusted on the surfaces of the wafers W by adjusting the distance Y from the innermost side in the movement path of the wafers W.

In the foregoing, it has been described that the arrangement of the microwave introducing mechanisms 224 is adjusted such that the plasma density increases as the distance from the center of the rotary mounting table 110 increases, as an example. However, the present disclosure is not limited to this. For example, the power of each microwave introducing mechanism 224 may be adjusted. Specifically, the power of the microwave introducing mechanisms 224 may be set to be sequentially increased from the inside row toward the outside row. With this arrangement, the plasma may be generated such that the density of the plasma is increased as the distance from the center of the rotary mounting table 110 is increased.

Meanwhile, it has been described that each microwave introducing mechanism 224 is configured such that microwaves may be introduced into the microwave introducing mechanism 224 from a side thereof so that a slug driving unit 260 may be provided on the top of the microwave introducing mechanism 224, as an example. However, the configuration of the microwave introducing mechanism 224 is not limited to this. For example, the microwave introducing mechanism 224 may be configured such that microwaves may be introduced into the microwave introducing mechanism from the top thereof such that the slug driving unit 260 may be provided on a side thereof.

(Heater)

Next, descriptions will be made on a case where heaters for heating the wafers W are provided in the plasma processing apparatus 100 illustrated in FIG. 1 with reference to drawings. When the heaters are provided, the plasma processing apparatus 100 may function as an apparatus performing a film forming processing or an etching processing which requires heating of the wafers W.

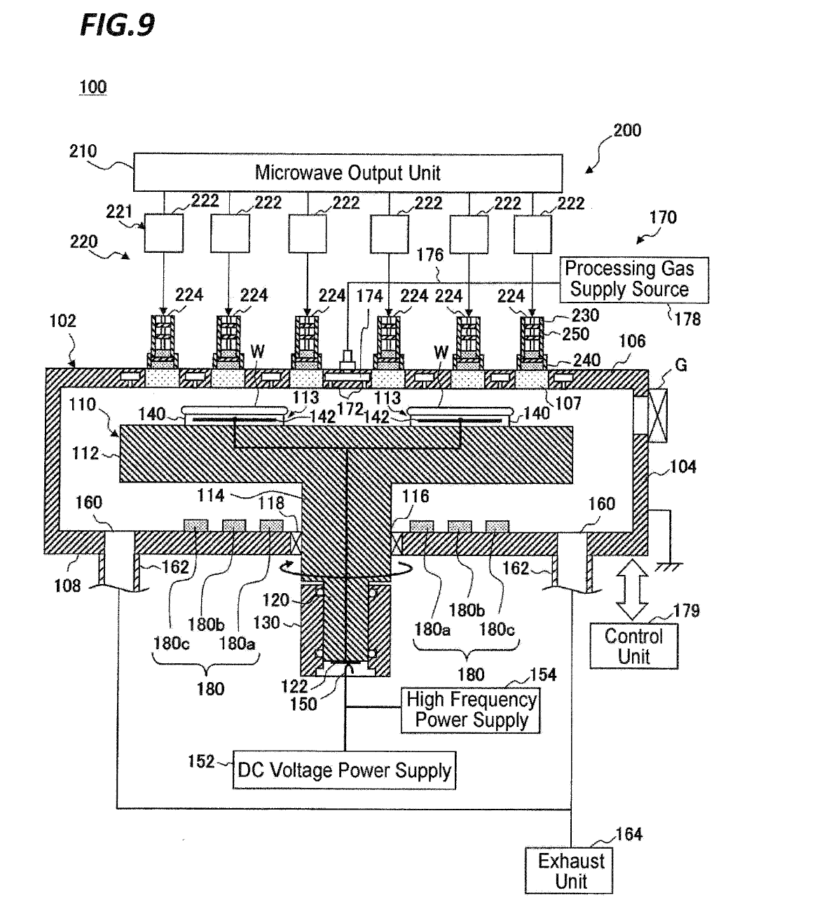

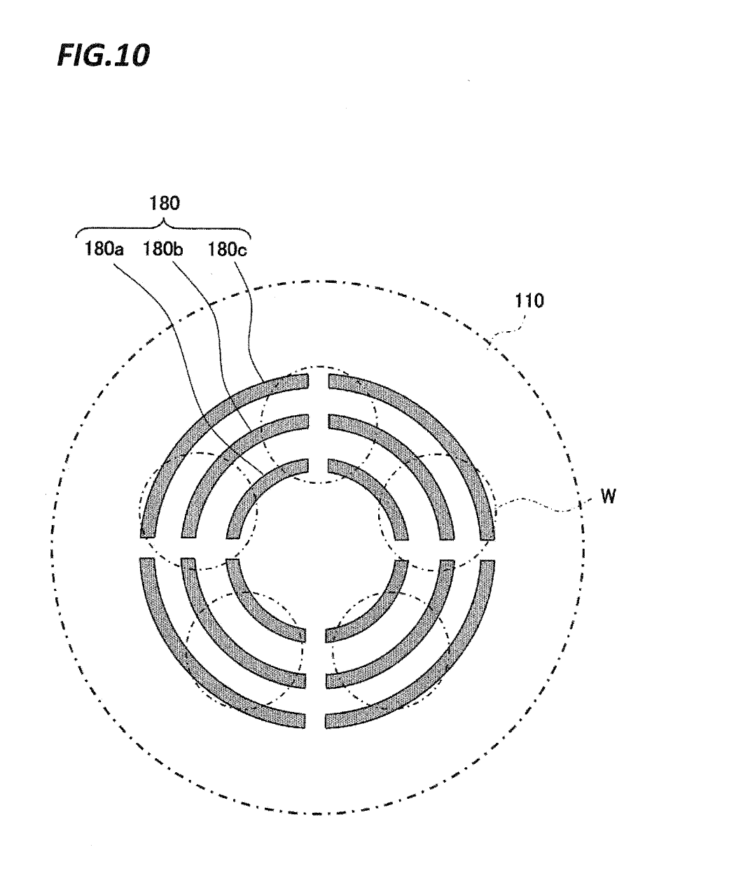

The heaters for adjusting the temperature of the wafers W may be provided to be spaced apart from the rotary mounting table 110 or directly provided on the rotary mounting table 110. Here, descriptions will be made on a case where the rotary mounting table 110 is heated by heaters which are disposed to be spaced downwardly apart from the rotary mounting table 110, as an example. FIGS. 9 and 10 are views for describing an exemplary configuration in which heaters are provided below the rotary mounting table. In FIG. 10, the positions of the rotary mounting table 110 and the wafers W above heaters 180 are indicated by one-dot chain lines.

In the plasma processing apparatus 100 illustrated in FIG. 9, annular heaters 180 are disposed below the rotary mounting table 110. The heaters 180 herein are disposed to be spaced apart from the rotary mounting table 110 not to interfere with the rotating movement of the rotary mounting table 110. For example, as illustrated in FIG. 9, the heaters 180 may be disposed on the bottom portion 108 of the processing chamber 102. Thus, the rotary mounting table 110 may be heated by the annular heaters 180 from the lower side while being rotated, and as a result, the temperature of each wafer W may be adjusted to a predetermined temperature.

In this case, the rotary mounting table 110 may be divided into multiple zones from the center side to the peripheral edge side thereof, and the heaters may be disposed in the zones, respectively, so that the temperature of each zone may be independently controlled. For example, when the rotary mounting table 110 is divided into three zones from the center side to the peripheral edge side as illustrated in FIG. 10, a heater 180a of the inner zone that passes a portion which is close to the innermost side of the movement path of the wafers W when the rotary mounting table 110 is rotated, a heater 180c of the outer zone that passes a portion close to the outermost side of the movement path of the wafers W, and a heater 180b that passes the middle zone therebetween are attached to the bottom portion 108 of the processing chamber 102 as illustrated in FIG. 9. Thus, each zone may be independently heated and controlled.

Meanwhile, each of the heaters 180a, 180b, 180c may be disposed by dividing it into multiple parts as illustrated in FIG. 9, or installed as a single body. When each of the heaters 180a, 180b, 180c is installed by dividing it into multiple parts, the number of divided parts is not limited to that illustrated in FIG. 9.

Since the heaters 180 illustrated in FIGS. 9 and 10 heat the rotary mounting table 110 from a distant place, heating may be efficiently performed when the rotary mounting table 110 is made of an insulating material having a high heat conductivity such as, for example, quartz or carbon, and the heaters 180 are configured as radiant heat type heaters. In addition, according to this configuration, high temperature heating is also possible. Thus, the plasma processing apparatus 100 may function as a film forming apparatus that performs a film forming processing that requires high temperature heating of wafers W.

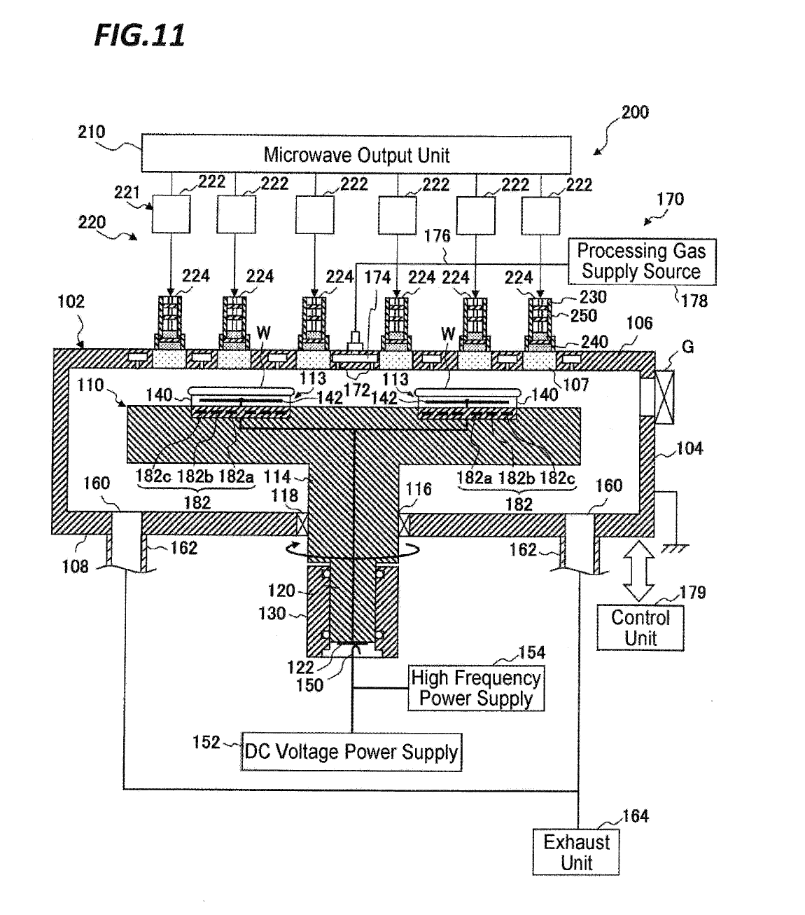

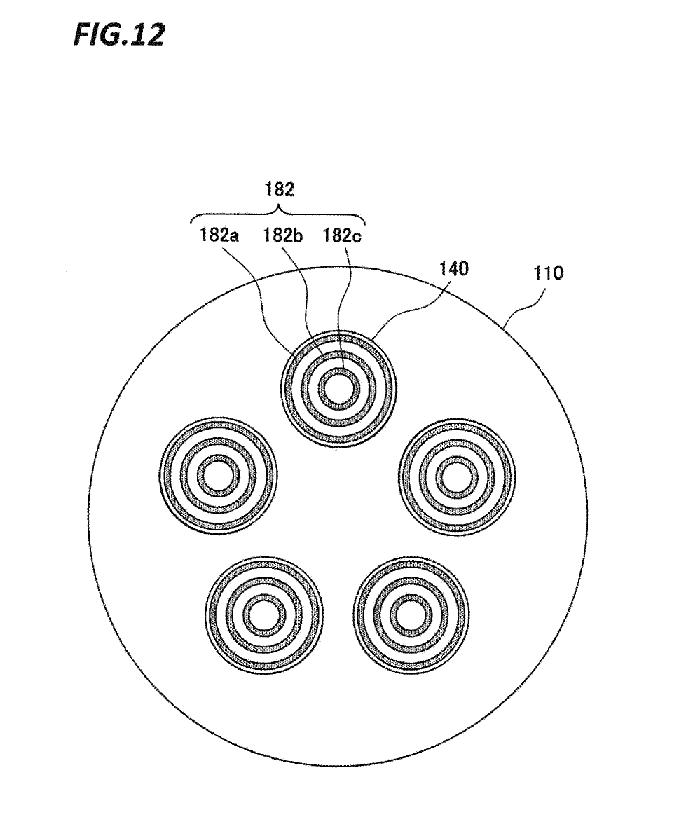

Subsequently, descriptions will be made on a case where heaters for adjusting the temperature of wafers W are directly installed on the rotary mounting table 110, as an example. FIGS. 11 and 12 are views for describing an exemplary configuration in which heaters are provided on the rotary mounting table.

In the plasma processing apparatus 100 illustrated in FIG. 11, annular heaters 182 are directly disposed on the rotary mounting table 110. The heaters 182 herein are disposed below the electrostatic chucks 140, respectively. For example, as illustrated in FIG. 11, the annular heaters 182 may be embedded in the rotary mounting table 110 below the electrostatic chucks 140, respectively. Thus, the wafers W may be respectively heated by the annular heaters 182 while the rotary mounting table 110 is rotated, and as a result, the temperature of each wafer W may be adjusted to a predetermined temperature.

In this case, each wafer W may be divided concentrically into multiple zones from the center side to the peripheral edge side, and the heaters may be disposed in the zones, respectively, so that the temperature of each zone may be independently controlled. For example, when each wafer is divided into three zones from the center side to the peripheral edge side as illustrated in FIG. 12, a heater 182a of the inner zone which is closest to the center of the wafer W, a heater 182c of the outer zone which is closest to the peripheral edge of the wafer W, and a heater 182b of the middle zone therebetween are attached to the bottom side of the electrostatic chuck 140, as illustrated in FIG. 11. As a result, each zone may be independently heated and controlled. In addition, in this case, the temperature of each wafer W may be independently controlled.

Since the heaters 182 illustrated in FIGS. 11 and 12 heat the wafers W from the bottom side of the electrostatic chucks 140, respectively, a fine in-plane temperature control may be performed on the surface of each wafer W. Due to this, the plasma processing apparatus 100 may function as an etching apparatus which performs an etching processing which requires a fine temperature control of a wafer W.

(Processing Gas Supplying Section)

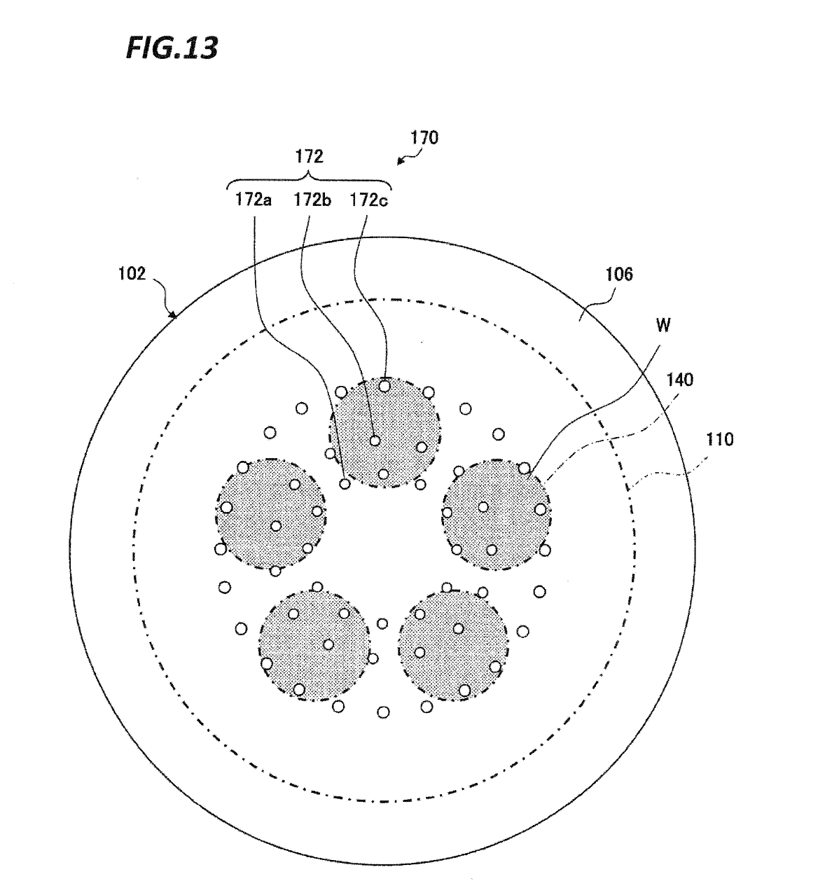

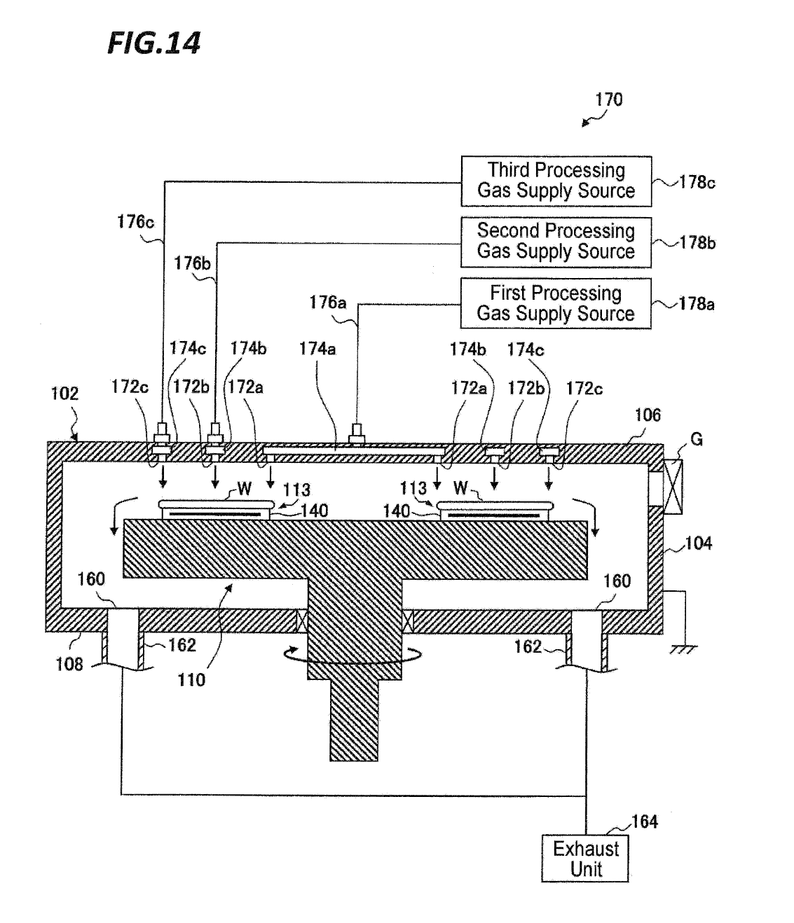

Subsequently, descriptions will be made on another exemplary configuration of the processing gas supplying section 170 in the plasma processing apparatus 100 illustrated in FIG. 1 with reference to drawings. FIGS. 13 and 14 are views for describing another exemplary configuration of the processing gas supplying section. In FIG. 14, the plasma generating section 200 is omitted. In FIG. 13, the positions of the rotary mounting table 110 and the wafers W are indicated by one-dot chain lines.

As illustrated in FIG. 13, the processing gas supplying section 170 herein is divided into multiple zones from the center side to the peripheral edge side of the rotary mounting table 110, and the heaters are respectively disposed in the zones so that the processing gas may be independently supplied to each zone. For example, as illustrated in FIG. 13, when the processing gas supply unit 170 is divided into three zones from the center side to the peripheral edge side of the rotary mounting table 110, gas holes 172a, gas holes 172c, and gas holes 172b are formed to be arranged side by side annularly in rows in the circumferential direction in the inside zone passing through a portion which is closest to the innermost side of the movement path of the wafers W when the rotary mounting table 110 is rotated, in the outside zone passing through a portion which is closest to the outermost side of the movement path of the wafers W, and in the middle zone therebetween, respectively.

As illustrated in FIG. 14, the gas holes 172a, 172b, 172c respectively communicate with gas flow paths 174a, 174b, 174c which are independently formed within the ceiling 106 of the processing chamber 102. The gas flow paths 174a, 174b, 174c are connected with first, second and third processing gas supply sources 178a, 178b, 178c through pipes 176a, 176b, 176c, respectively.

The first, second, and third processing gas supply sources 178a, 178b, 178c may supply the same species of gases or the different species of gases. The processing gases from the processing gas supply sources 178a, 178b, 178c are supplied to the gas flow paths 174a, 174b, 174 while the flow rates thereof are controlled to predetermined flow rates by flow rate control units such as, for example, mass flow controllers (MFCs) (not illustrated), respectively.

According to the gas supply unit 170 illustrate in FIG. 13, the processing gases from the processing gas supply sources 178a, 178b, 178c may be independently ejected from the gas holes 172a, 172b, 172c, respectively, as illustrated in FIG. 14. The processing gases ejected from the gas holes 172a, 172b, 172c are ejected toward the wafers W on the rotary mounting table 110, and discharged from the exhaust ports 160 through the space between the side portion of the rotary mounting table 110 and the side wall 104 of the processing chamber 102.

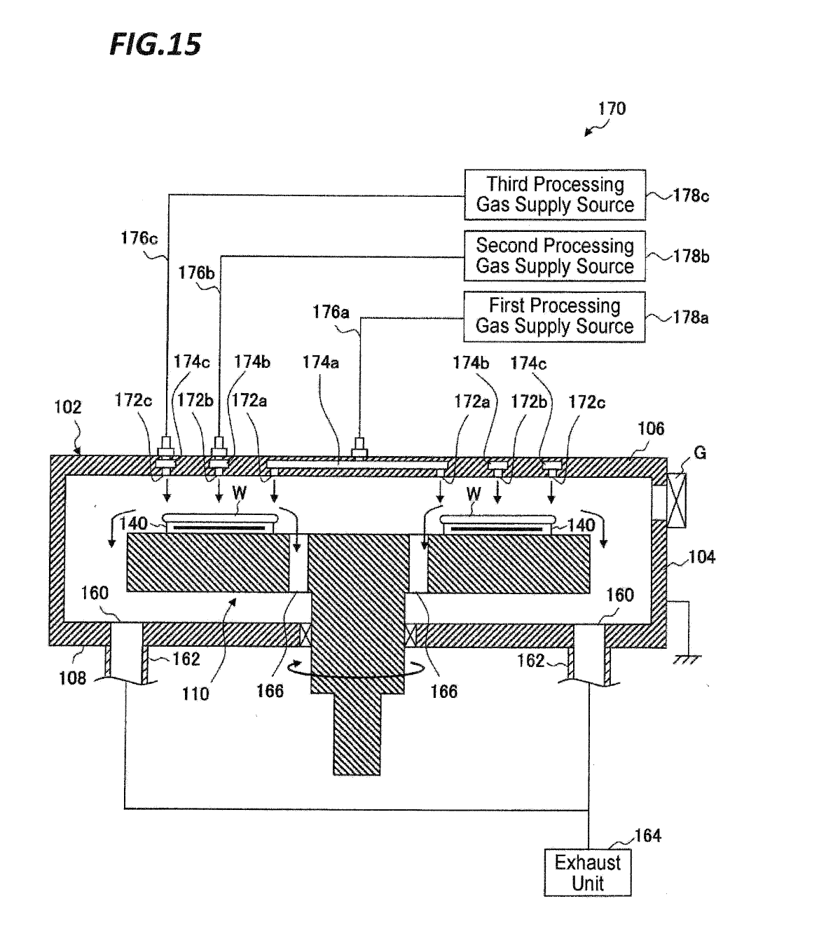

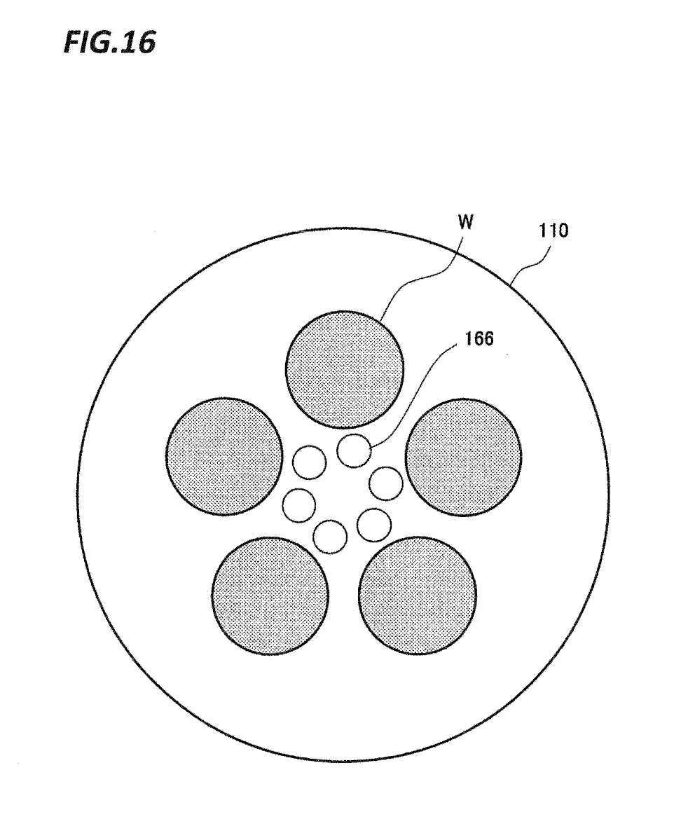

Meanwhile, a through hole, through which the processing gases pass, may be provided in the rotary mounting table 110 illustrated in FIG. 14 so as to form flows of the processing gases directed toward the center side of the rotary mounting table 110 from the top surfaces of the wafers W. Specifically, for example, as illustrated in FIGS. 15 and 16, a plurality of through holes 166 are formed to be arranged side by side annularly more inside than the movement path of the wafers W when the rotary mounting table 110 is rotated.

According to this, as illustrated in FIG. 16, the processing gases ejected toward the wafers W on the rotary mounting table 110 from the gas holes 172a, 172b, 172c flow not only into the space between the side portion of the rotary mounting table 110 and the side wall 104 of the processing chamber 102, but also into the through holes 166 of the rotary mounting table 110 to be discharged from the exhaust ports 160. As a result, not only the flows of processing gases directed toward the peripheral edge side of the rotary mounting table 110 through the top of each wafer W, but also the flows of processing gases directed toward the center side may be formed so that processing uniformity in the radial direction of the rotary mounting table 110 may be further enhanced on each wafer W.

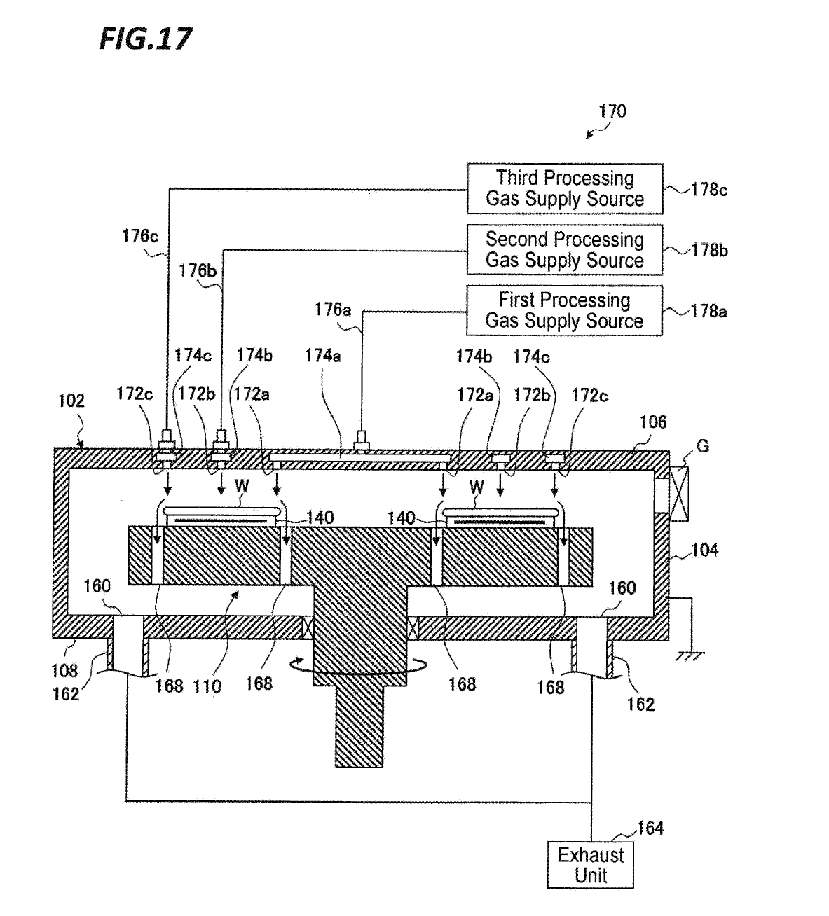

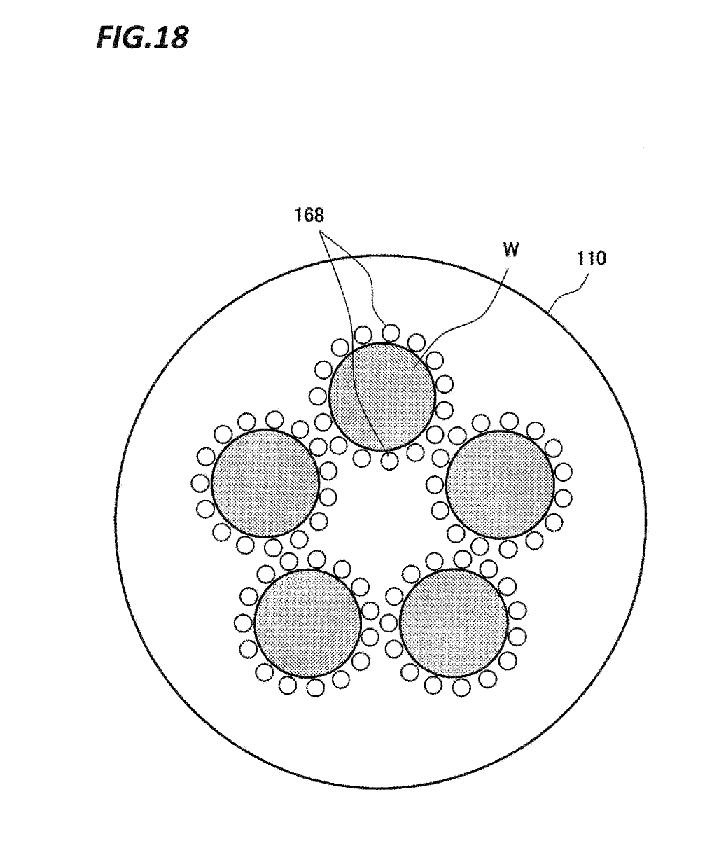

In addition, the through holes 166 in the rotary mounting table 110 are not limited to those illustrated in FIGS. 15 and 16. For example, as illustrated in FIGS. 17 and 18, through holes 168 may be formed to surround each wafer W placed on the rotary mounting table 110. According to this, on the wafer W, not only the flows of processing gases directed toward the peripheral edge side of the rotary mounting table 110, but also the flows of processing gases directed toward the center side may be formed. In addition, since the through holes 168 illustrated in FIG. 16 are formed around each wafer W, the flows of processing gases directed from the center side to the entire peripheral edge side may be formed on each wafer as illustrated in FIG. 15 such that processing uniformity on the entire surface of each wafer W may be further enhanced.

(Modified Example of Rotary Mounting Table)

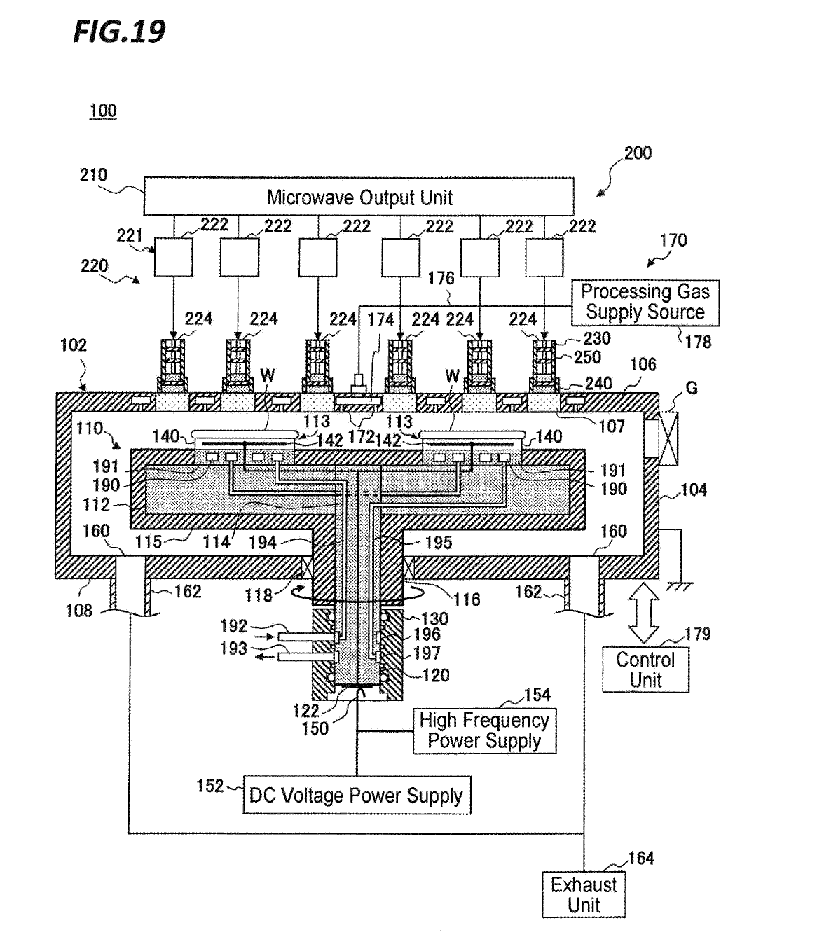

Next, another exemplary configuration of the rotary mounting table applicable to the plasma processing apparatus according to the present exemplary embodiment will be described with reference to the drawings. Here, descriptions will be made on a case where the rotary mounting table 110 is configured to be capable of cooling each wafer W in the plasma processing apparatus 110 illustrated in FIG. 1, as an example. According to this, the plasma processing apparatus 100 may function as an apparatus for performing an etching processing while cooling wafers W. FIG. 19 is a cross-sectional view illustrating another exemplary configuration of the plasma processing apparatus illustrated in FIG. 1 in which another rotary mounting table is applied. In FIG. 19, since the components other than the rotary mounting table are the same as those illustrated in FIG. 1, detailed descriptions thereof will be omitted.

The rotary mounting table 110 illustrated in FIG. 19 is configured by covering a rotary table 112 and a rotary shaft 114 which are made of a highly heat-conductive material, for example, a metal such as, for example, aluminum, with an insulation member 115 such as, for example, ceramic. The upper end of the rotary shaft 114 herein is inserted into a hole formed at the center of the rotary table 112, and the lower end of the rotary shaft 114 protrudes from the insulation member 115 to be inserted into a mounting table driving unit 130.

Each wafer placement unit 113 on the rotary mounting table 110 is provided with a cooling mechanism configured to cool a wafer W. The cooling mechanism is configured by providing a coolant flow path 190 within a disc-shaped protrusion 191 made of a metal having a high conductivity such as, for example, aluminum, and formed, for example, on the top surface of the rotary table 112 so that a coolant (e.g., cooling water) having a predetermined temperature and supplied from a chiller unit (not illustrated) is introduced into the coolant flow path 190 from an inlet piping 192, and the coolant is led out from an outlet piping 193 so that the coolant 190 can be circulated and supplied.

Each of the inlet piping 192 and the outlet piping 193 communicates with the coolant flow path 190 of the wafer W on each wafer placement unit 113 through an inlet line 194 and an outlet line 195, respectively, in which the inlet line 194 and the outlet line 195 are provided within the rotary table 112 and the rotary shaft 114.

The inlet line 194 and the outlet line 195 within the rotary shaft 114 communicate with annular recesses 196, 197, respectively, which are formed on the entire side surface of the lower end portion 120 of the rotary shaft 114. The upper and lower portions of the annular recesses 196, 197 are sealed by seal members such as, for example, O-rings. Meanwhile, the inlet piping 192 and the outlet piping 193 are disposed to face the annular recesses 196, 197 at the side surface of the mounting table driving unit 130, respectively.

According to the cooling mechanism with this configuration, even if the rotary mounting table 110 is rotated, the inlet piping 192 and the outlet piping 193 always face and communicate with the annular recesses 196, 197, and as a result, coolant may be circulated in the coolant flow path 190 of each wafer placement unit 113 while rotating the rotary mounting table 110. Thus, even if the plasma processing is being performed while rotating the rotary mounting table 110, each wafer W may be cooled so as to control the temperature thereof to a predetermine temperature.

Meanwhile, a heat transfer gas supply mechanism (not illustrated) may be provided in each wafer placement unit 113 of the rotary mounting table 110 to supply a heat transfer gas such as, for example, He gas to a gap between the top surface of the electrostatic chuck 140 and the rear surface of a wafer W. The wafer temperature may be maintained at a desired temperature by supplying the heat transfer gas so as to enhance the heat conductivity to the rear surfaces of the wafers. Although not particularly illustrated in connection with the heat transfer gas supply mechanism, like the cooling mechanism described above, in connection with the heat transfer gas supply mechanism, a gas line communicating with the top surface of each electrostatic chuck 140 is provided within the rotary table 112 and the rotary shaft 114 so that the gas line communicates with an annular recess formed around the entire side surface of the lower end portion 120 of the rotary shaft 114. In addition, the heat transfer gas inlet piping faces the annular recess to introduce the heat transfer gas into the annular recess so that the heat transfer gas may be supplied to the rear surface of each wafer W while rotating the rotary mounting table 110. Meanwhile, when both the cooling mechanism and the heat transfer gas supply mechanism are provided, the annular recesses thereof are provided at the positions shifted on the side surface of the lower end portion 120 of the rotary shaft 114 so that the annular recesses do not interfere with each other.

In addition, heaters may be provided in the plasma processing apparatus 100 illustrated in FIG. 19 to heat wafers W. For example, as illustrated in FIGS. 9 and 10 described above, the heaters 180 may be provided to be spaced downwardly away from the rotary mounting table 110, or, as illustrated in FIGS. 11 and 12, the heaters 182 may be provided below each electrostatic chuck 140 of the rotary mounting table 110.

However, even if the rotary table 112 made of a metal such as, for example, aluminum is employed as illustrated in FIG. 19, when the heaters 182 are directly provided on the rotary table 112 below each electrostatic chuck 140, a high frequency power for bias may leak out to the heaters 182 through the rotary table 112 when the high frequency power for bias is applied to each electrostatic chuck 140.

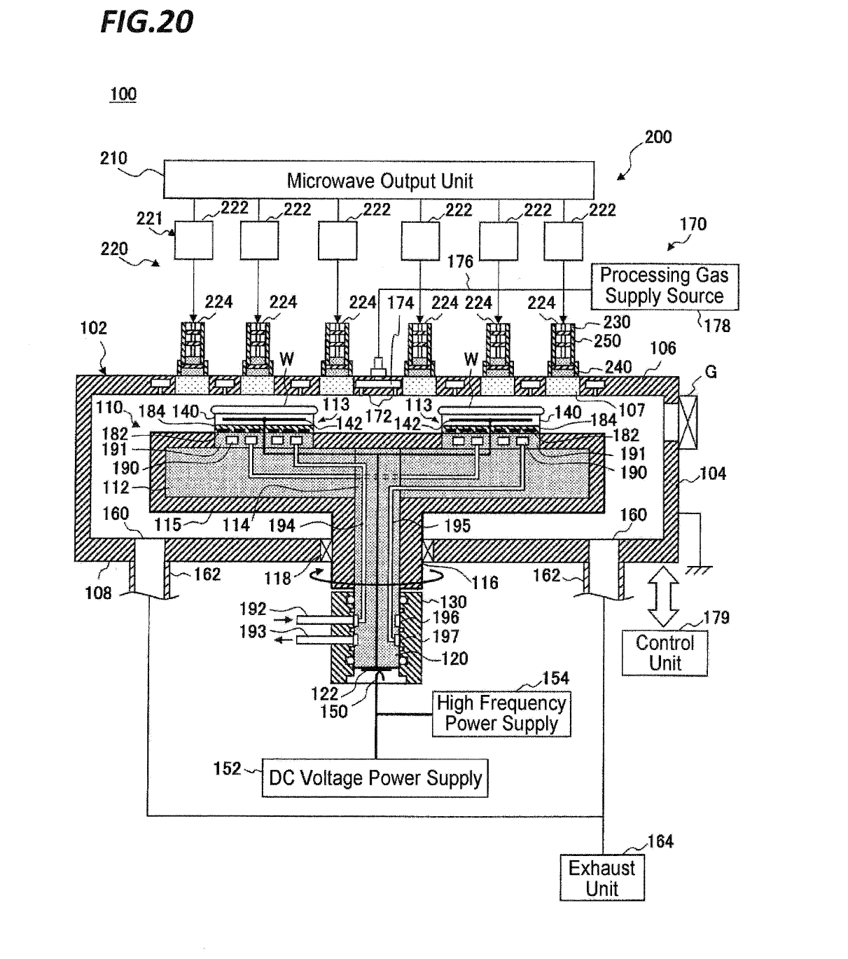

For this reason, in the present exemplary embodiment, when the rotary table 112 made of a metal is applied, a ground member 184 having a ground potential is provided between the rotary table 112 (the disc-shaped protrusions 191) and each electrostatic chuck 140, for example, as illustrated in FIG. 20, and the heaters 182 (182a, 182b, 182c) are disposed in the ground member 184. The ground member 184 may be made of an insulation member such as, for example, ceramic. In this way, it is possible to prevent the high frequency power for bias applied to each electrostatic chuck 140 from leaking out to the heaters 182. Meanwhile, instead of the ground member 184, the heaters 182 may be provided with a filter to block the high frequency power for bias.

Meanwhile, the configuration of the processing gas supplying section 170 illustrated in FIGS. 13 and 14 may also be applied to the plasma processing apparatus 100 illustrated in FIGS. 19 and 20, and the through holes 166 illustrated in FIGS. 15 and 16 and the through holes 168 illustrated in FIGS. 17 and 18 may be formed in the rotary mounting table 110.

(Another Exemplary Configuration of Plasma Generating Section)

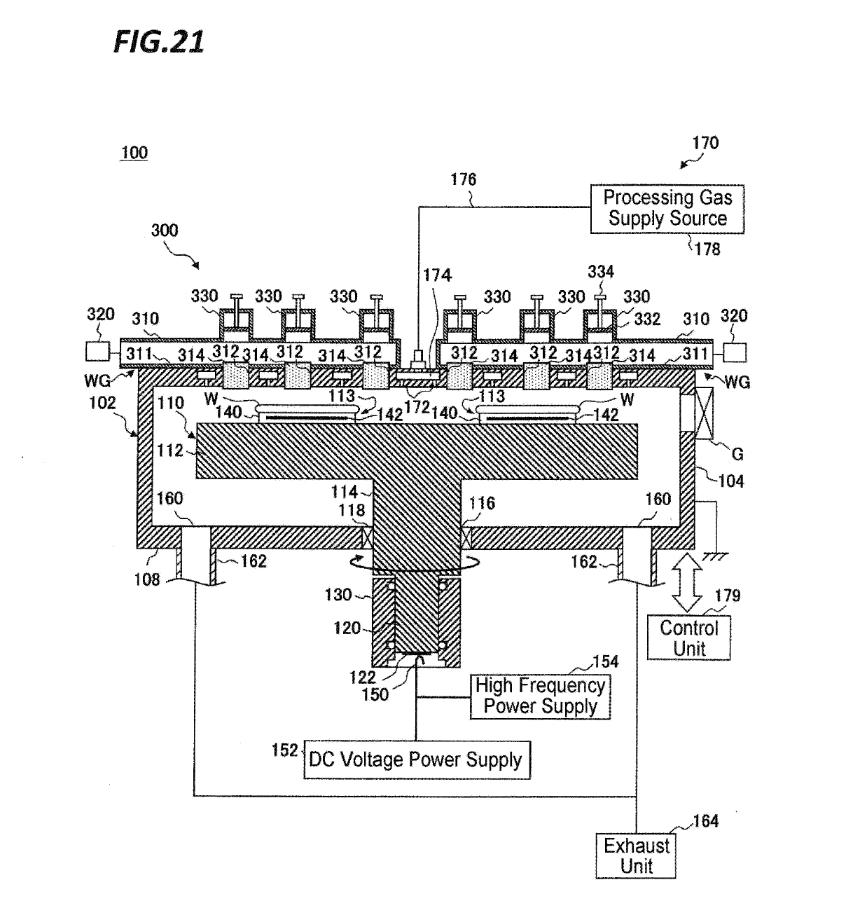

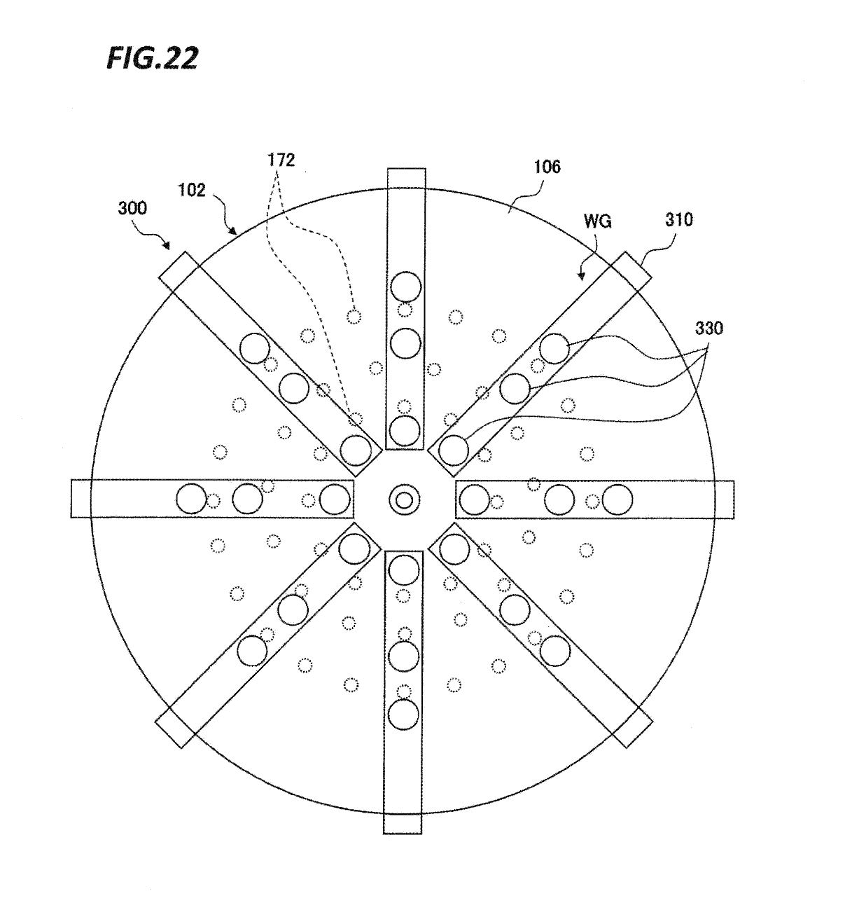

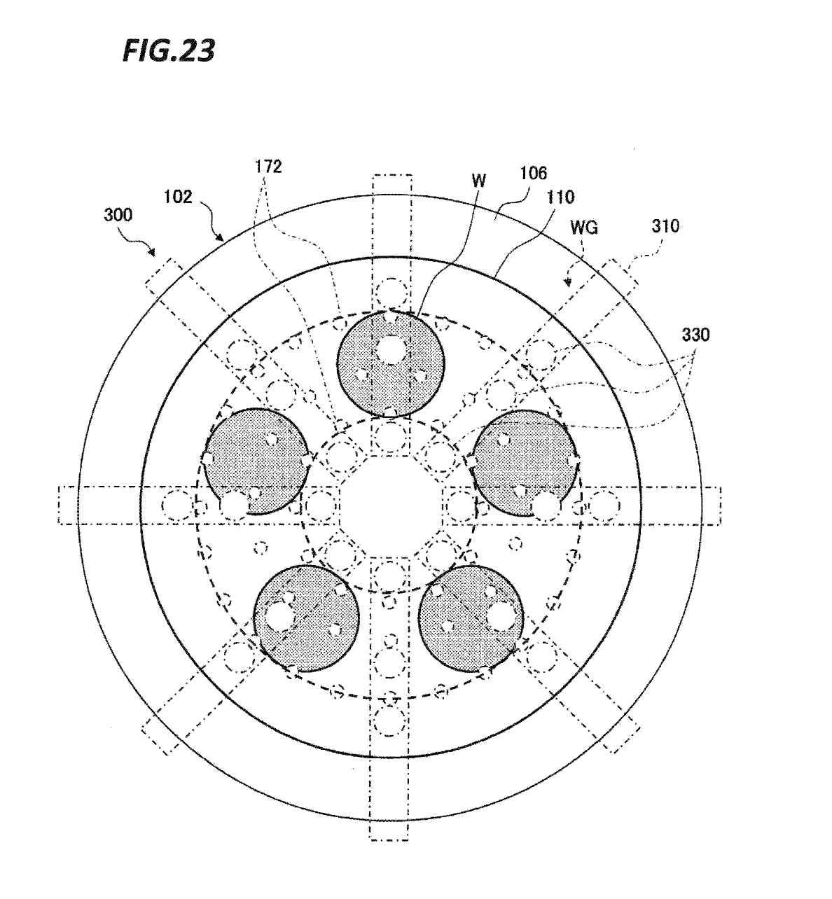

Next, another exemplary configuration of the plasma generating section applicable to the plasma processing apparatus 100 according to the present exemplary embodiment will be described with reference to drawings. Here, descriptions will be made on a plasma generating section 300 in which a plurality of waveguides are disposed in the ceiling 106 to generate microwave plasma within the processing chamber 102, as an example. FIG. 21 is a cross-sectional view illustrating another exemplary embodiment of the plasma generating section, and FIG. 22 is a plan view of the plasma generating section 300 illustrated in FIG. 21 which is viewed from the top side, and FIG. 23 is a plan view of the rotary mounting table 110 viewed from the top side.

Meanwhile, since the components other than the plasma generating section 300 are the same as those illustrated in FIG. 1, detailed descriptions thereof will be omitted. In FIG. 22, the positions of the gas holes 172 are indicated by dotted lines, in FIG. 23, the positions of the gas holes 172 disposed on the rotary mounting table 110, waveguides 310 for guiding microwaves, and plungers 330 are indicated by one-dot chain lines, and the movement path (inside and outside) of the wafers W when the rotary mounting table 110 is rotated is indicated by dotted lines.

The plasma generating section 300 illustrated in FIG. 21 is provided with a plurality of waveguides 310 to supply microwaves into the processing chamber 102. A plurality of waveguides 310 are provided. Each waveguide 310 is a rectangular waveguide and defines a waveguide path (WG) extending radially from the center side to the peripheral edge side of the ceiling 106. Here, descriptions will be made on an example in which eight waveguides 310 are provided in the ceiling 106, as illustrated in FIG. 22. Meanwhile, the number and shape of the waveguides 310 are not limited thereto.

Each waveguide 310 is connected with a microwave generator 320. The microwave generator 320 is configured to generate microwaves of, for example, about 2.45 GHz, and supply the microwaves to the waveguides 310.

Each waveguide 310 has a lower conductor portion 311 defining a waveguide path WG from the lower side. The lower conductor portion 311 is in contact with the top surface of the ceiling 106 of the processing chamber 102. A plurality of openings 312 are formed in the lower conductor portions and the ceiling 106 to penetrate the lower conductor portions 311 and the ceiling 106. Dielectric members 314 made of a dielectric material such as, for example, quartz, are attached by being respectively inserted into the openings 312 to protrude downwardly from the bottom surface of the ceiling 106. Thus, the ceiling 106 may also function as a microwave transmission plate.

Above the waveguides 310, plungers 330 are disposed to face the dielectric members 314, respectively. Each plunger 330 includes a reflector 332 and a positioning mechanism 334. The reflector 332 of each plunger 330 faces one of the dielectric members 314 through the waveguide 310. The positioning mechanism 334 of each plunger 330 functions to adjust a distance from the waveguide path WG of the reflector 332 in the axis Z direction.

In consideration of efficiency and in-plane uniformity when each wafer W is processed by plasma while the rotary mounting table 110 is rotated, the plungers 330 and the dielectric members 314 are arranged in multiple rows such that the multiple rows are spaced apart from each other from an area more inside than the movement path of the wafers W to an area more outside than the movement path of the wafers W in which each row is formed by arranging the plungers 330 and the dielectric members 314 annularly side by side in the circumferential direction of the rotary mounting table 110, as illustrated in FIGS. 22 and 23. Meanwhile, the numbers of the plungers 330 or dielectric members 314 and the number of rows thereof are not limited to those illustrated in the drawings.

According to the plasma generating section 300 configured as described above, a processing gas is supplied to the inside of the processing chamber 102 by the processing gas supplying section 170 while rotating the rotary mounting table 110 on which five wafers W are placed. In addition, microwaves are generated by the microwave generator 320. The generated microwaves are propagated to the plurality of waveguides 310 and discharged to the inside of the processing chamber 102 from the plurality of dielectric members 314. As a result, plasma of the processing gas is generated in the processing chamber 102 so that a predetermined plasma processing is performed on each wafer W.

Meanwhile, also in the plasma processing apparatus 100 illustrated in FIG. 21, the configuration of the processing gas supplying section 170 illustrated in FIGS. 13 and 14 may be applied, and the through holes 166 illustrated in FIGS. 15 and 16 and the through holes 168 illustrated in FIGS. 17 and 18 may be formed in the rotary mounting table 110. Further, any one or both of the heaters 180 illustrated in FIGS. 9 and 10 and the heaters 182 illustrated in FIGS. 11 and 12 may be provided, and the rotary mounting table 110 illustrated in FIGS. 19 and 20 may be applied.

(Exemplary Configuration of Substrate Processing Apparatus)

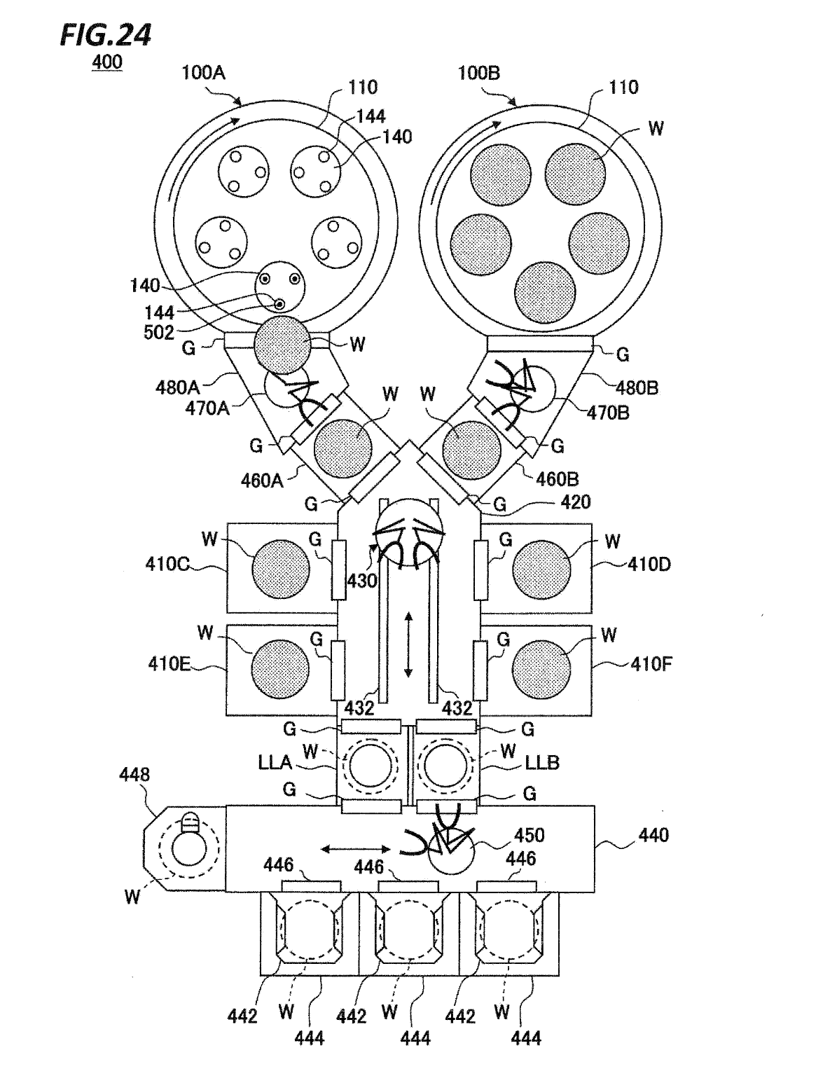

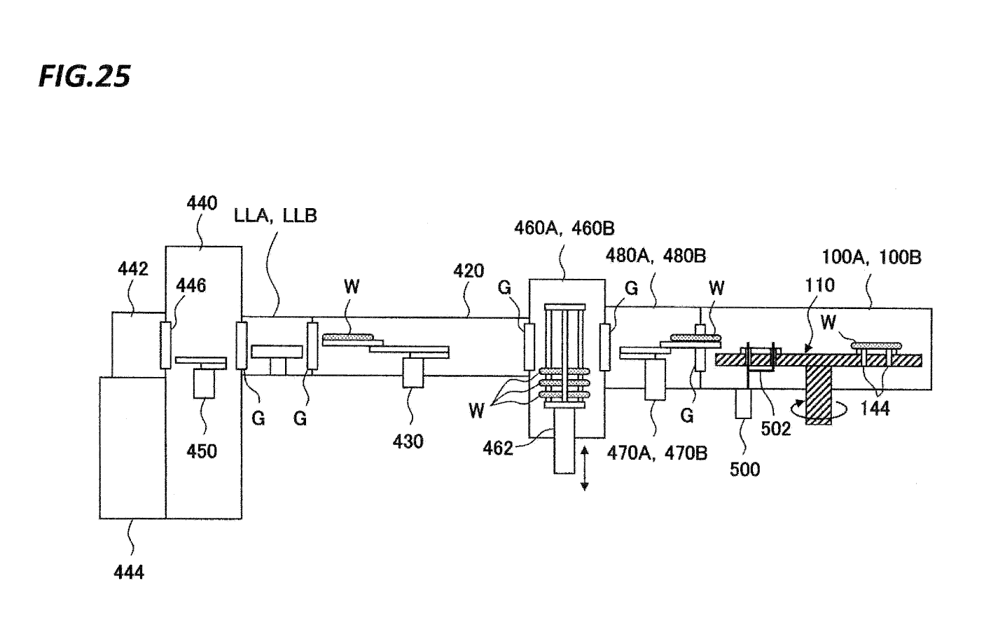

Next, an exemplary configuration of a substrate processing apparatus including a vacuum conveyance chamber, to which the plasma processing apparatus according to the present exemplary embodiment described above may be connected, will be described with reference to the drawings. FIG. 24 is a horizontal cross-sectional view illustrating a schematic configuration of a substrate processing apparatus in the present exemplary embodiment. FIG. 25 is a vertical cross-sectional view illustrating the substrate processing apparatus illustrated in FIG. 24.

The substrate processing apparatus 400 illustrated in FIG. 24 includes a vacuum conveyance chamber (common conveyance chamber) 420 to which a plurality of semi-batch type plasma processing apparatuses 100 and a plurality of single type plasma processing apparatuses 410 may be connected.

The vacuum conveyance chamber 420 illustrated in FIG. 24 is configured in a pentagonal shape which is long in one direction. To the vacuum conveyance chamber 420, two semi-batch type plasma processing apparatuses 100A, 100B are connected to the tip end of the vacuum conveyance chamber 420 through gate valves G, four single type plasma processing apparatuses 410C, 410D, 410E, 410F in total are connected to the both sides of the vacuum conveyance chamber 420 (two apparatuses at each side) through gate valves G, and two load-lock chambers LLA, LLB are connected to the base end of the vacuum conveyance chamber 420 through gate valves G.

The load-lock chambers LLA, LLB function to temporarily maintain wafers W to adjust pressure, and then pass the wafers W to the next stage. Within each of the load-lock chambers LLA, LLB, a delivery table is provided to place a wafer W thereon.

Within the vacuum conveyance chamber 420, a conveyance arm apparatus (first conveyance arm apparatus) 430 of a double arm mechanism provided with two conveyance arms are installed to be slidable along guide rails 432 installed in the longitudinal direction of the vacuum conveyance chamber 420.

In the conveyance arm apparatus 430, a position of the sliding direction is set in advance according to a chamber to access. Here, descriptions will be made on a case where positions in the vicinity of the tip end side and the base end side of the vacuum conveyance chamber 420 are set in advance, as an example.

For example, when accessing any of the semi-batch type plasma processing apparatuses 100A, 100B and two single type plasma processing apparatuses 420C, 420D, the conveyance arm apparatus 430 is disposed at the position in the vicinity of the tip end side. By rotating the conveyance arm at this position, the conveyance arm may be advanced/retreated with respect to a plasma processing apparatus to access so as to perform carry-in/out of a wafer W.

In addition, when accessing any of two single type plasma processing apparatuses 410E, 410F and two load-lock chambers LLA, LLB, the conveyance arm apparatus 430 is disposed at the position in the vicinity of the base end side. By rotating the conveyance arm at this position, the conveyance arm may be advanced/retreated in a plasma processing direction to access so as to perform carry-in/out of a wafer W.

The load-lock chambers LLA, LLB are connected to an atmosphere conveyance chamber 440 having an atmospheric-pressure atmosphere through gate valves G, respectively. The atmosphere conveyance chamber 440 is configured such that a storage container 442, in which a plurality of wafers W (e.g., 25 wafers corresponding to one lot) are accommodated, may be set on a storage table 444. On a side wall of the atmosphere conveyance chamber 440, load ports 446 as wafer W input ports are formed to correspond to storage tables 444, respectively.

In the atmosphere conveyance chamber 440, an orienter (pre-alignment stage) 448 serving as a wafer W positioning apparatus is provided. The orienter 447 is provided therein with, for example, an optical sensor configured to optically detect the peripheral edges of the rotary mounting table and the wafer W, so as to detect an orientation flat or a notch of the wafer W, thereby positioning the wafer W.

In the atmosphere conveyance chamber 440, a conveyance arm apparatus 450 of a double arm mechanism including two conveyance arms is installed to be slidable in the longitudinal direction of the atmosphere conveyance chamber 440. The conveyance arm apparatus 450 is configured to be capable of carrying wafers W into/out of each storage container 442 through a load port 446, and carrying wafers W into/out of the load-lock chambers LLA, LLB through the gate valves G.

According to the substrate processing apparatus 400, when a new wafer W is loaded in a load-lock chamber from the atmosphere conveyance chamber 440 as needed, the new wafer W is taken out by the conveyance arm apparatus 430 and conveyed to a plasma processing apparatus in which a processing is to be performed.

However, in the semi-batch type plasma processing apparatuses 100A, 100B according to the present exemplary embodiment, a plasma processing is initiated after a plurality of wafers W are set on the rotary mounting table 110, as described above. For this reason, when the semi-batch type plasma processing apparatuses 100A, 100B are directly connected with the vacuum conveyance chamber 420 through the gate valves, the wafers W are delivered one by one while operating the conveyance arm apparatus 450 of the atmosphere conveyance chamber 440 and the conveyance arm apparatus 430 of the vacuum conveyance chamber 420. In this way, it takes a lot of time to set all the wafers W on the rotary mounting table 110.

Thus, in the substrate processing apparatus 400 according to the present exemplary embodiment, for example, as illustrated in FIGS. 24 and 25, the semi-batch type plasma processing apparatuses 100A, 100B may be respectively connected to the vacuum conveyance chamber 420 through buffer chambers 460A, 460B each of which may temporarily accommodate a number of wafers W, of which the number is equal to or more than the number of wafers which may be placed on each of the rotary mounting tables 110. Each of the buffer chambers 460A, 460B is configured by liftably installing a substrate holding unit 462 which is capable of arranging and holding a plurality of wafers W in the vertical direction, for example, as illustrated in FIG. 25.

According to this, for example, when a plurality of wafers W to be subsequently processed are conveyed into and kept in the buffer chambers 460, for example, while the plasma processing is performed in the semi-batch type plasma processing apparatuses, only the delivery of the next wafers W between the buffer chambers 460 and the rotary mounting tables 110 is required when the next wafers W are set on the rotary mounting tables 110. Thus, the time required for carrying in/out the wafers W may be greatly reduced.

In this case, as illustrated in FIGS. 24 and 25, hermetically sealed conveyance chambers 480A, 480B, each of which includes a conveyance arm apparatus (second conveyance arm apparatus) 470A or 470B, may be installed between the semi-batch type plasma processing apparatuses 100A, 100B and the buffer chambers 460A, 460B, respectively. The semi-batch type plasma processing apparatuses 100A, 100B and the conveyance chambers 480A, 480B, the conveyance chambers 480A, 480B and the buffer chambers 460A, 460B, and the buffer chambers 460A, 460B and the vacuum conveyance chamber 420 are connected with each other through gate valves G, respectively.

According to this, the delivery of wafers W between each of the semi-batch type plasma processing apparatuses 100A, 100B and each of the buffer chambers 460A, 460B may be fully performed by the conveyance arm apparatus 470A or 470B of each of the conveyance chambers 480A, 480B, and as a result, the whole wafer W conveyance throughput may be enhanced. Meanwhile, each of the conveyance arm apparatuses 470A, 470B may be configured as a double arm mechanism including two conveyance arms as illustrated in FIG. 24, or as a single arm mechanism including one conveyance arm.

In addition, when the semi-batch type plasma processing apparatuses 100A, 100B are directly connected to the buffer chambers 460A, 460B, respectively, without providing the conveyance chambers 480A, 480B, the conveyance arm apparatuses 470A, 470B may be installed in the buffer chambers 460A, 460B, respectively.

(Wafer Lifter Mechanism)

Descriptions will be made on a case where a lifter mechanism configured to raise/lower wafers W with lift pins to/from each electrostatic chuck 140 of the rotary mounting table 110 is provided in the semi-batch type plasma processing apparatus 100 according to the present exemplary embodiment described above.

As described above, the rotary mounting table 110 of the plasma processing apparatus 100 according to the present exemplary embodiment is rotated. Thus, even when performing carry-in/out of wafers W, the wafers W may be placed on the electrostatic chucks 140 one by one while rotating the rotary mounting table 110.

For this reason, when the lifter mechanism is provided in the plasma processing apparatus 100, it is not necessary to install the lifter mechanisms on all the electrostatic chucks 140. It is sufficient if the wafers W may be raised or lowered at least at a position where the wafers W face the gate valves G.

Thus, in the present exemplary embodiment, for example, as illustrated in FIG. 25, a lifter mechanism 500 configured to raise/lower lifter pins 502 is installed in the vicinity of the gate valve G, to be spaced apart downwardly from the rotary mounting table 110. In addition, at least three through holes 144 are formed through the rotary mounting table 110 and the electrostatic chuck 140 in an area in the rotary mounting table 110 where each electrostatic chuck 140 is disposed, as holes that allow the lifter pins 502 to pass therethrough from the bottom side.

Thus, as illustrated in FIG. 24, the lifter mechanism 500 is driven when an electrostatic chuck 140 is positioned to face the gate valve G so that the lifter pins 502 are inserted into the through holes 144 of the electrostatic chuck 140 and raised until the lifer pins 502 protrude from the top side of the electrostatic chuck 140. Then, the wafer W may be raised from the electrostatic chuck 140.

The lifter mechanism 500 may have any configuration as long as it may raise/lower the lifter pins 502. The lifter mechanism 500 may be configured, for example, by liftably supporting the lifter pins in a casing and providing a motor driving the lifter pins 502 to be raised/lowered. A seal member is provided around each lifter pin 502 to seal.

As the seal member herein, an O-ring may be used. Alternatively, a magnetic fluid seal may also be used. The magnetic fluid is obtained by dispersing, minute particles of, for example, Fe₃O₄ in a colloid state in a dispersion medium, and the magnetic fluid seal maintains the magnetic fluid along magnetic flux lines formed by a magnet in a gap where the seal is disposed. The magnetic fluid maintained in the gap by magnetic force functions like a liquid-phase O-ring without flowing out even if a pressure difference exists. Thus, the magnetic fluid seal does not cause contact of solids, unlike the O-ring, and as a result, friction loss may be reduced and occurrence of particles by friction may be prevented.

Meanwhile, the magnetic fluid seal performs sealing with liquid as described above. Thus, when sealing is performed on linearly moving shafts such as, for example, the lifter pins 502, the magnetic fluid may be dragged due to the movement of the shafts. Thus, the lifting stroke of the lifter pins 502 may not be set too long. Thus, when the lifting stroke of the lifter pins 502 is set long, the lifter pins 502 may be lifted using, for example, a link mechanism.

Here, an exemplary configuration of a lifter mechanism 500 using the magnetic fluid seal will be described with reference to drawings. The lifter mechanism 500 liftably supports a shaft 506 through a magnetic fluid seal 510, in which the shaft 506 is lifted within a case 504 by a motor (not illustrated), for example.

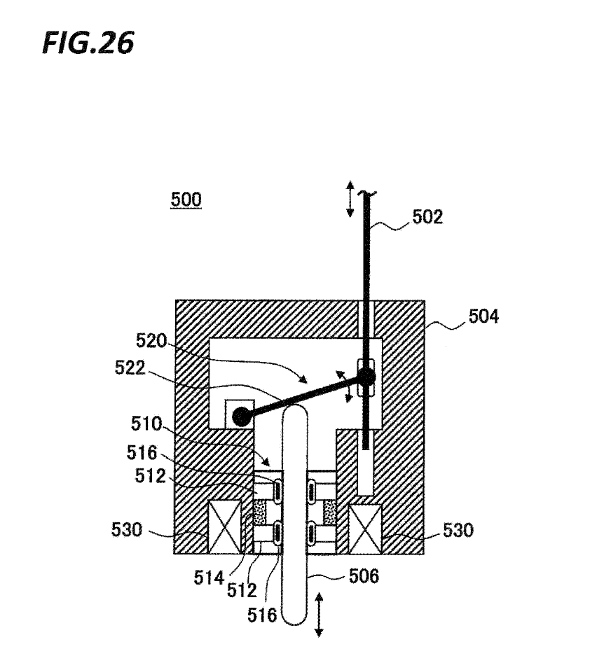

The magnetic fluid seal 510 is configured such that a magnetic fluid 516 is maintained in a gap between ball pieces 514 interposed between magnets 512 and the shaft 506, for example, as illustrated in FIG. 26. According to this, the magnetic fluid 516 may be maintained by the magnetic flux lines of the magnets 512 to be capable of sealing the shaft 506.

Meanwhile, a lifter pin 502 is liftably supported by a link mechanism 520. The link mechanism 520 includes a rotatable link 522 and thus has a function of converting the rotating movement of the link 522 into the lifting movement of the lifter pin 502. By lifting the link 522 with the shaft 506, the lifter pin 502 supported on the tip end of the link 522 is lifted. According to this, even if the lifting stroke of the shaft 506 is short, the lifting stroke of the lifter pin 502 may be set long.

Meanwhile, a heater 530 may be provided within the case 504 of the lifter mechanism 500 so as to further suppress occurrence of particles. The magnetic fluid seal 510 herein may be applied as the seal member 118 of the rotary mounting table 110 illustrated in FIG. 1. In addition, a magnetic fluid actuator may be provided instead of the magnetic fluid seal 510 to lift and drive the shaft 506. In addition, the lifter pin may be directly lifted by the magnetic fluid actuator.

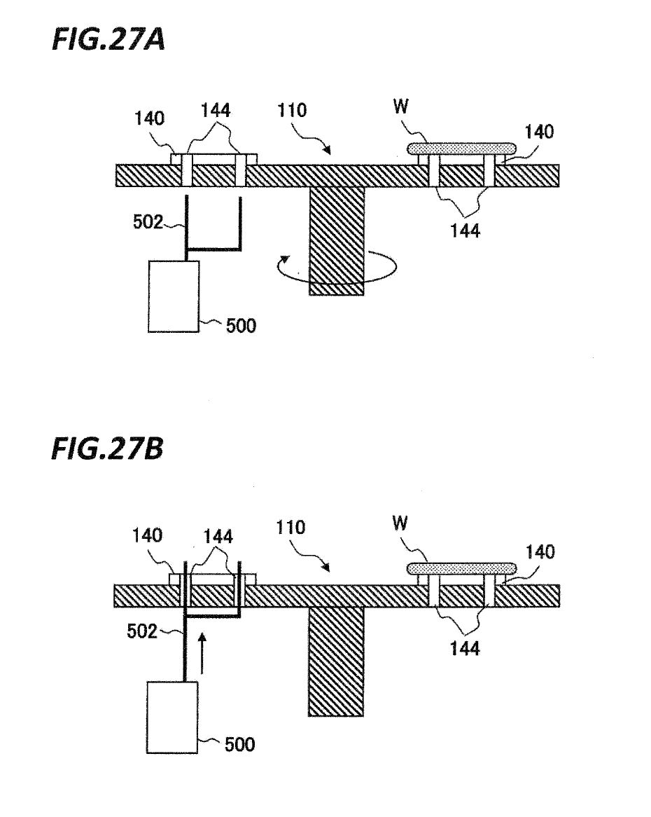

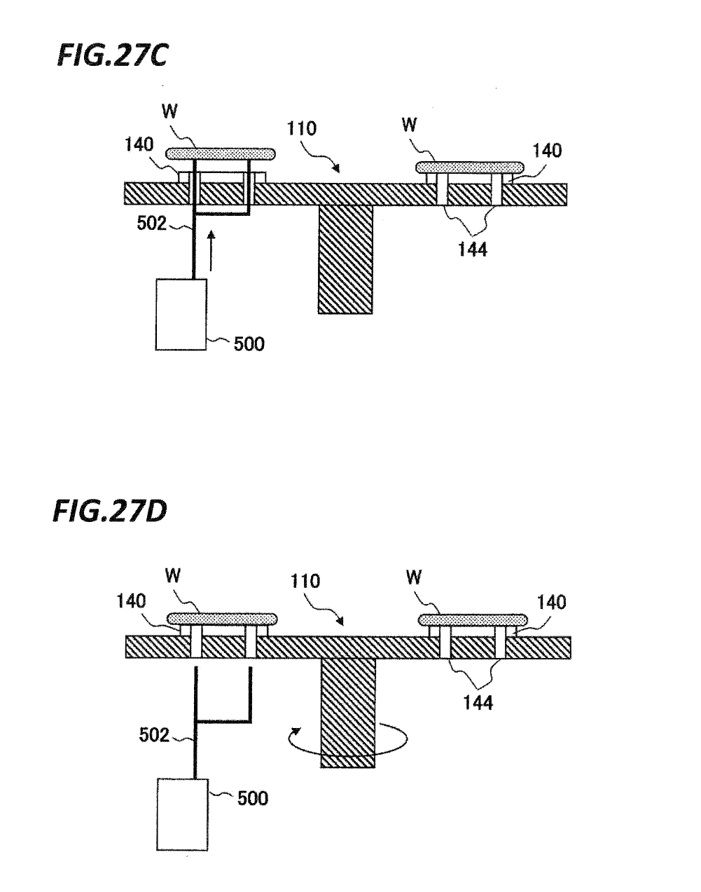

Next, descriptions will be made on operations in the case where wafers W are placed on the rotary mounting table 110 by the plasma processing apparatus 100 provided with the lifter mechanism 500 described above with reference to the drawings. FIGS. 27A to 27D are explanatory views of operations when wafers are placed on the rotary mounting table in the present exemplary embodiment. Here, descriptions will be made on a case where the wafers W are placed on the electrostatic chucks 140 of the plasma processing apparatus 100A illustrated in FIG. 25.

For example, when a wafer W is placed on an electrostatic chuck 140 of the rotary mounting table 110, for example, as illustrated in FIG. 25, the rotary mounting table 110 is rotated such that the electrostatic chuck 140 is moved to the position where the electrostatic chuck 140 faces the gate valve G, as illustrated in FIGS. 25 and 27A. In addition, the lifter pins 502 are raised by the lifter mechanism 500 so that the lifter pins 502 are inserted into the through holes 144, as illustrated in FIG. 27B.

Then, a wafer W is carried into the plasma processing apparatus 100A by the conveyance arm apparatus 470A through the gate valve G, and is placed on the lifter pins 502, as illustrated in FIG. 27C. Then, the lifter pins 502 are lowered by the lifter mechanism 500 and the wafer W is lowered and placed on the electrostatic chuck 140 as illustrated in FIG. 27D. The lifter pins 502 are lowered to be returned to the original positions thereof, i.e. the positions where the lifter pins 502 do not interfere with the rotating movement of the rotary mounting table 110.

Thereafter, the operations of FIGS. 27A to 27D are repeated, so as to place a wafer W on each of the electrostatic chucks 140 of the rotary mounting table 110. When the wafers W are placed on all the electrostatic chucks 140 in this way, the rotary mounting table 110 is rotated to initiate a plasma processing.

Meanwhile, in the substrate processing apparatus 400 illustrated in FIG. 24, descriptions has been made on the case where the buffer chambers 430A, 430B are provided between the plasma processing apparatuses 100A, 100B and the vacuum conveyance chamber 420. Without being limited to this, however, the buffer chambers 430A, 430B may be installed at any placement positions of the single type plasma processing apparatuses 410C, 410D, 410E, 410F, instead of them. In addition, the number of the semi-batch type plasma processing apparatuses and the number of the single type plasma processing apparatuses are not limited to those illustrated in FIG. 24. In addition, the vacuum conveyance apparatus connecting them with each other are not limited to those illustrated in FIG. 24.

Although, exemplary embodiments of the present disclosure have been described with reference to the accompanying drawings, the present disclosure is, of course, not limited to the exemplary embodiments. It is obvious that a person skilled in the art may conceive various changes and modifications within the scope defined in the claims, and it is understood that the changes and modifications are naturally belonging to the technical scope of the present disclosure.

### INDUSTRIAL APPLICABILITY

The present disclosure is applicable to a plasma processing apparatus in which a plurality of processing target substrates such as, for example, semiconductor wafers and liquid crystal substrates, are placed and processed within a processing chamber, and a substrate processing apparatus including the same.

### DESCRIPTION OF SYMBOLS

100 (100A, 100B): plasma processing apparatus, 102: processing chamber, 104: side wall, 106: ceiling, 107: dielectric member, 108: bottom portion, 110: rotary mounting table, 112: rotary table, 113: wafer placement unit, 114: rotary shaft, 115: insulation member, 116: through hole, 118: seal member, 120: lower end portion, 122: power feeding terminal, 130: mounting table driving unit, 140: electrostatic chuck, 142: electrode, 144: through hole, 150; power feeding brush, 152: DC voltage power supply, 154: high frequency power supply, 160: exhaust port, 162: exhaust pipe, 164: exhaust unit, 166: through hole, 168: through hole, 170: processing gas supplying section, 172 (172a, 172b, 172c): gas hole, 174 (174a, 174b, 174c): gas flow path, 176 (176a, 176b, 176c): pipe, 178: processing gas supply source, 178a: first processing gas supply source, 178b: second processing gas supply source, 178c: third processing gas supply source, 179: control unit, 180 (180a, 180b, 180c): heater, 182 (182a, 182b, 182c): heater, 184: ground member, 190: coolant flow path, 191: disc-shaped protrusion, 192: inlet piping, 193: outlet piping, 194: inlet line, 195: outlet line, 196, 197: annular recess, 200: plasma generating section, 210; microwave output unit, 212: microwave power supply, 214: microwave oscillator, 216: amplifier, 218: distributor, 220: microwave supply unit, 221: antenna module, 222: amplifier unit, 224: microwave introducing mechanism, 230: waveguide path, 240: antenna unit, 250: tuner, 252a, 252b: slug, 260: slug driving unit, 274: microwave power inlet port, 276: power feeding antenna, 300: plasma generating section, 310: waveguide, 311: lower conductor portion, 312: opening, 314; dielectric member, 320: microwave generator, 330: plunger, 332: reflector, 334: positioning mechanism, 400: substrate processing apparatus, 100A, 100B: semi-batch type plasma processing apparatus, 410C, 410D, 410E, 410F: single type plasma processing apparatus, 420: vacuum conveyance chamber, 430: conveyance arm apparatus, 430A, 430B: buffer chamber, 432: guide rail, 440: atmosphere conveyance chamber, 442: storage container, 444: storage table, 446: load port, 450: conveyance arm apparatus, 460A, 460B: buffer chamber, 462: substrate holding unit, 470A, 470B: conveyance arm apparatus, 480A, 480B: conveyance chamber, 500: lifter mechanism, 502: lifter pin, 510: magnetic fluid seal, 520: link mechanism, 530: heater, LLA, LLB: load-lock chamber, G: gate valve, W: wafer

1. A plasma processing apparatus that performs a plasma processing on a plurality of substrates placed in a processing chamber, the plasma processing apparatus comprising:
a rotary mounting table supported by a rotatory shaft rotatably disposed within the processing chamber, and including a plurality of substrate placement units, which are arranged side by side in a circumferential direction to place the substrates thereon;
a processing gas supplying section configured to supply a processing gas into the processing chamber;
a plasma generating section provided on a ceiling of the processing chamber to face the rotary mounting table, and including a plurality of microwave introducing mechanisms configured to generate plasma of the processing gas, wherein the plurality of microwave introducing mechanisms are arranged in multiple rows which are spaced apart from each other from an area more inside than a movement path of the substrates when the rotary mounting table is rotated to an area more outside than the movement path of the substrates, each row of the microwave introducing mechanisms being formed by arranging the microwave introducing mechanisms annularly side by side along the circumferential direction; and
an exhaust unit configured evacuate an inside of the processing chamber,
the microwave introducing mechanisms are arranged at regular intervals in the circumferential direction, and the rows are arranged such that intervals between the rows are narrowed from the inside toward the outside.

2. (canceled)

3. The plasma processing apparatus of claim 1, wherein the plurality of microwave introducing mechanisms are arranged in three or more rows from the inside to the outside,
the innermost row of the microwave introducing mechanisms is arranged more inside than the movement path of the substrates, and
the outermost row of the microwave introducing mechanisms is arranged more outside than the movement path of the substrates.

4. The plasma processing apparatus of claim 3, wherein the outermost row of the microwave introducing mechanisms is spaced apart from the outermost side of the movement path of the substrates by a distance according to a distance between the microwave introducing mechanisms and the rotary mounting table.

5. The plasma processing apparatus of claim 1, wherein powers of the microwave introducing mechanisms are set to be sequentially increased from the inside row to the outside row.

6. The plasma processing apparatus of claim 1, wherein the processing gas supplying section includes a plurality of gas holes on the ceiling of the processing chamber to introduce the processing gas, the plurality of gas holes being arranged in multiple rows spaced apart from each other from the inside of the movement path of the substrates to the outside of the movement path of the substrates, each row of the gas holes being formed by arranging the gas holes annularly side by side along the circumferential direction.

7. The plasma processing apparatus of claim 6, wherein a gas flow rate supplied from the gas holes is adapted to be adjusted for each row.

8. The plasma processing apparatus of claim 1, wherein the rotary mounting table is formed with through holes along the circumferential direction more inside than the movement path of the substrates, the processing gas passing through the through holes.

9. The plasma processing apparatus of claim 1, wherein each of the substrate placement units includes an electrostatic chuck configured to electrostatically attract a substrate, and
the electrostatic chuck includes an electrode plate within an insulator, and is configured such that both of a DC voltage for electrostatically attracting the substrate and a high frequency power for bias for applying a high frequency bias to the substrate are applicable to the electrode plate.

10. The plasma processing apparatus of claim 9, wherein a terminal is provided on the rotary shaft of the rotary mounting table to be electrically connected to an electrode of each of the substrate placement units so that the DC voltage and the high frequency power for bias are fed to the terminal of the rotary shaft side while the rotary mounting table is rotated.

11. The plasma processing apparatus of claim 1, wherein a heat transfer gas is supplied to a gap between each of the substrate placement units and the substrate placed on each of the substrate placement units.

12. The plasma processing apparatus of claim 11, wherein a heat transfer gas inlet recess is provided around the rotary shaft of the rotary mounting table so that the heat transfer gas is supplied to the heat transfer gas inlet recess while the rotary mounting table is being rotated.

13. The plasma processing apparatus of claim 1, wherein a cooling mechanism configured to cool the substrate is provided below the electrostatic chuck of each of the substrate placement units, and
the cooling mechanism is configured to circulate a coolant in a coolant flow path provided in a conductive member.

14. The plasma processing apparatus of claim 13, wherein a coolant inlet recess and a coolant outlet recess are provided around the rotary shaft of the rotary mounting table to communicate with the coolant flow path, the coolant inlet recess and the coolant outlet recess being configured such that the coolant is introduced from the coolant inlet recess and led out from the coolant outlet recess while the rotary mounting table is rotated.

15. The plasma processing apparatus of claim 1, wherein each substrate placement unit of the rotary mounting table is provided with a through hole through the substrate placement unit and the rotary mounting table to insert a lifter pin, which raises the substrate from a lower side of the substrate, through the through hole so as to raise or lower the substrate with respect to the substrate placement unit, and
the lifter pin is put into/out from the through hole from/to a lower side of the through hole by a lifter mechanism provided on a bottom portion of the processing chamber to be spaced apart from the rotary mounting table.

16. The plasma processing apparatus of claim 15, wherein the lifter mechanism is configured to lift the lifter pin by a magnetic fluid actuator.

17. The plasma processing apparatus of claim 15, wherein the lifter pin is sealed by a magnetic fluid seal.

18. The plasma processing apparatus of claim 9, wherein, when the rotary mounting table is made of an insulating material, a heater configured to heat the substrate is disposed within the rotary mounting table below the electrostatic chuck of each of the substrate placement units, and
when the rotary mounting table is made of a conductive material, a heater configured to heat the substrate is disposed below the electrostatic chuck of each of the substrate placement units through a ground member having a ground potential.

19. The plasma processing apparatus of claim 18, wherein a plurality of heaters are arranged along the circumferential direction of each of the substrate placement units from the inside to the outside.

20. The plasma processing apparatus of claim 1, wherein a heater is disposed to be spaced downwardly apart from the rotary mounting table and provided to heat the rotary mounting table from a lower side.

21. A substrate processing apparatus provided with a vacuum conveyance chamber which is connected with a plasma processing apparatus that performs a plasma processing on a plurality of substrates disposed within a processing chamber,
wherein the plasma processing apparatus comprises:
a rotary mounting table supported by a rotatory shaft rotatably disposed within the processing chamber, and including a plurality of substrate placement units, which are arranged side by side in a circumferential direction to place the substrates thereon;
a processing gas supplying section configured to supply a processing gas into the processing chamber;
a plasma generating section provided on a ceiling of the processing chamber to face the rotary mounting table, and including a plurality of microwave introducing mechanisms configured to generate plasma of the processing gas, wherein the plurality of microwave introducing mechanisms are arranged in multiple rows which are spaced apart from each other from an area more inside than a movement path of the substrates when the rotary mounting table is rotated to an area more outside than the movement path of the substrates, each row of the microwave introducing mechanisms being formed by arranging the microwave introducing mechanisms annularly side by side along the circumferential direction; and
an exhaust unit configured evacuate an inside of the processing chamber,
the vacuum conveyance chamber is connected with the plasma processing apparatus via a buffer chamber, and
the buffer chamber is configured to temporarily accommodate the substrates which are equal to or more than a number to be capable of being placed on the rotary mounting table of the plasma processing apparatus.

22. The substrate processing apparatus of claim 21, wherein the substrates accommodated in the buffer chamber are carried out/in with respect to the vacuum conveyance chamber by a first conveyance arm apparatus provided in the vacuum conveyance chamber, and carried out/in with respect to the plasma processing apparatus by a second conveyance arm apparatus which is provided separately from the first conveyance arm apparatus.

23. The substrate processing apparatus of claim 22, wherein the second conveyance arm apparatus is provided in a hermetically sealed chamber connected between the buffer chamber and the plasma processing apparatus.
